(19) United States
(12) Patent Application Publication
(10) Pub. No.: US 2023/0018127 A1
(43) Pub. Date: Jan. 19, 2023

(54) MICROELECTRONIC DEVICES WITH CHANNEL SUB-REGIONS OF DIFFERING MICROSTRUCTURES, AND RELATED METHODS AND SYSTEMS

(71) Applicant: Micron Technology, Inc., Boise, ID (US)

(72) Inventors: Ramanathan Gandhi, Singapore (SG); Sock Mui Poh, Singapore (SG); Dmitry Mikulik, Singapore (SG); Dae Hong Eom, Singapore (SG); Moonhyeong Han, Singapore (SG); Aireus O. Christensen, Boise, ID (US); Chandrasekaran Venkatasubramanian, Boise, ID (US)

(21) Appl. No.: 17/379,338

(22) Filed: Jul. 19, 2021

(51) Int. Cl. H01L 27/1157; H01L 27/11565; H01L 25/065

(52) U.S. Cl. CPC H01L 27/1157; H01L 27/11565; H01L 25/0652

(57) ABSTRACT

A microelectronic device includes a stack structure comprising a vertically alternating sequence of insulative structures and conductive structures arranged in tiers. At least one pillar extends through the stack structure. The at least one pillar includes at least one insulative material and a channel structure horizontally surrounding the at least one insulative material. The at least one channel structure comprises sub-regions of semiconductor material. At least one of the sub-regions exhibits a different microstructure than at least one other of the sub-regions. Additional microelectronic devices are also disclosed, as are related methods and electronic systems.

### TECHNICAL FIELD

Embodiments of the disclosure relate to the field of microelectronic device design and fabrication. More particularly, the disclosure relates to methods for forming microelectronic devices (e.g., memory devices, such as 3D NAND memory devices) having tiered stack structures that include vertically alternating conductive structures and insulative structures, to related systems, and to methods for forming such structures and devices.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically alternate conductive materials with insulating (e.g., dielectric) materials. The conductive materials function as control gates for, e.g., access lines (e.g., word lines) of the memory cells. Vertical structures (e.g., pillars comprising channel structures and tunneling structures) extend along the vertical string of memory cells. A drain end of a string is adjacent one of the top and bottom of the vertical structure (e.g., pillar), while a source end of the string is adjacent the other of the top and bottom of the pillar. The drain end is operably connected to a bit line, while the source end is operably connected to a source line. A 3D NAND memory device also includes electrical connections between, e.g., access lines (e.g., word lines) and other conductive structures of the device so that the memory cells of the vertical strings can be selected for writing, reading, and erasing operations.

The channel structures of the pillars of 3D NAND memory devices may be configured as “hollow” channel structures, with a channel material horizontally encircling a center or core of the pillar. Electrons travel through the channel structures during operations effecting writing, reading, and erasing of the memory cells provided by the pillar.

As the features of 3D NAND memory devices are scaled to smaller sizes to increase device density on a base structure, reduced feature sizes tend to present challenges in maintaining the performance parameters, such as electron mobility and electrical current (e.g., “string current”) through the channel material, and also such as data retention by the memory cells. Accordingly, designing and fabricating microelectronic devices, such as 3D NAND memory devices, continues to present challenges.

### BRIEF DESCRIPTION OF THE DRAWINGS

FIG. 1 is a cross-sectional, elevational, schematic illustration of a microelectronic device structure, wherein multiple channel sub-regions of differing microstructures horizontally surround—and also underlay—a central fill material of a pillar structure, in accordance with embodiments of the disclosure.

FIG. 2A through FIG. 2D are enlarged illustrations of box 102 of FIG. 1, schematically illustrating, in cross-section, the differing microstructures of the channel sub-regions of the microelectronic device structure of FIG. 1, according to embodiments of the disclosure, wherein:

FIG. 2A illustrates a channel structure with a large-grain inner sub-region and a small-grain outer sub-region;

FIG. 2B illustrates a channel structure with a large-grain inner sub-region and an amorphous outer sub-region;

FIG. 2C illustrates a channel structure with a large-grain inner sub-region and an amorphous outer sub-region, the amorphous outer sub-region including a dopant; and

FIG. 2D illustrates a channel structure with a large-grain inner sub-region and a small-grain outer sub-region, the small grains including a dopant species.

FIG. 3 is a cross-sectional, elevational, schematic illustration of a microelectronic device structure that may include the microelectronic device structure of FIG. 1, such that the illustration of FIG. 1 may be an enlarged view corresponding to box 104 of FIG. 3, and including channel structures in accordance with any or all of FIG. 2A through FIG. 2D, in accordance with embodiments of the disclosure.

FIG. 4 is a top plan, schematic illustration of the microelectronic device structure of FIG. 3, wherein the view of FIG. 3 is taken along section line A-A of FIG. 4, and wherein the view of FIG. 1 is taken along section line B-B of FIG. 4, in accordance with embodiments of the disclosure.

FIG. 5A and FIG. 5B are each a cross-sectional, elevational, schematic illustration of a memory cell, in accordance with embodiments of the disclosure, wherein the illustrated area may corresponds to, e.g., box 106 of FIG. 1 and/or of FIG. 3.

FIG. 6 through FIG. 21 are cross-sectional, elevational, schematic illustrations of various stages of processing to fabricate the microelectronic device structures of FIG. 1 through FIG. 4, in accordance with embodiments of the disclosure, wherein:

FIG. 13A through FIG. 13D are enlarged illustrations of box 102 of FIG. 12, wherein FIG. 13A illustrates the stage of FIG. 12 in accordance with FIG. 2A, FIG. 13B illustrates the stage of FIG. 12 in accordance with FIG. 2B, FIG. 13C illustrates the stage of FIG. 12 in accordance with FIG. 2C, and FIG. 13D illustrates the stage of FIG. 12 in accordance with FIG. 2D;

FIG. 15A through FIG. 15D are enlarged illustrations of box 102 of FIG. 14, wherein FIG. 15A illustrates the stage of FIG. 14 in accordance with FIG. 2A, FIG. 15B illustrates the stage of FIG. 14 in accordance with FIG. 2B, FIG. 15C illustrates the stage of FIG. 14 in accordance with FIG. 2C, and FIG. 15D illustrates the stage of FIG. 14 in accordance with FIG. 2D; and

FIG. 17A through FIG. 17D are enlarged illustrations of box 102 of FIG. 16, wherein FIG. 17A illustrates the stage of FIG. 16 in accordance with FIG. 2A, FIG. 17B illustrates the stage of FIG. 16 in accordance with FIG. 2B, FIG. 17C illustrates the stage of FIG. 16 in accordance with FIG. 2C, and FIG. 17D illustrates the stage of FIG. 16 in accordance with FIG. 2D.

FIG. 22 through FIG. 25, along with FIG. 6 through FIG. 10, are cross-sectional, elevational, schematic illustrations of various stages of processing to fabricate the microelectronic device structure of FIG. 25, in accordance with embodiments of the disclosure, wherein the stage of FIG. 22 equally represents the stage of FIG. 10 and follows the stages of FIG. 6 through FIG. 9, and wherein:

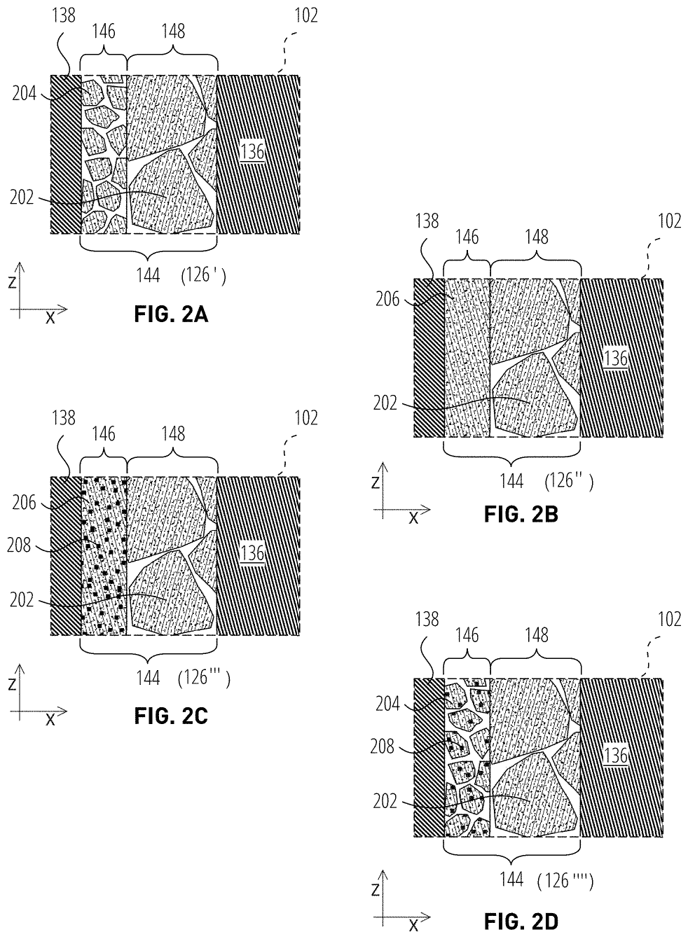

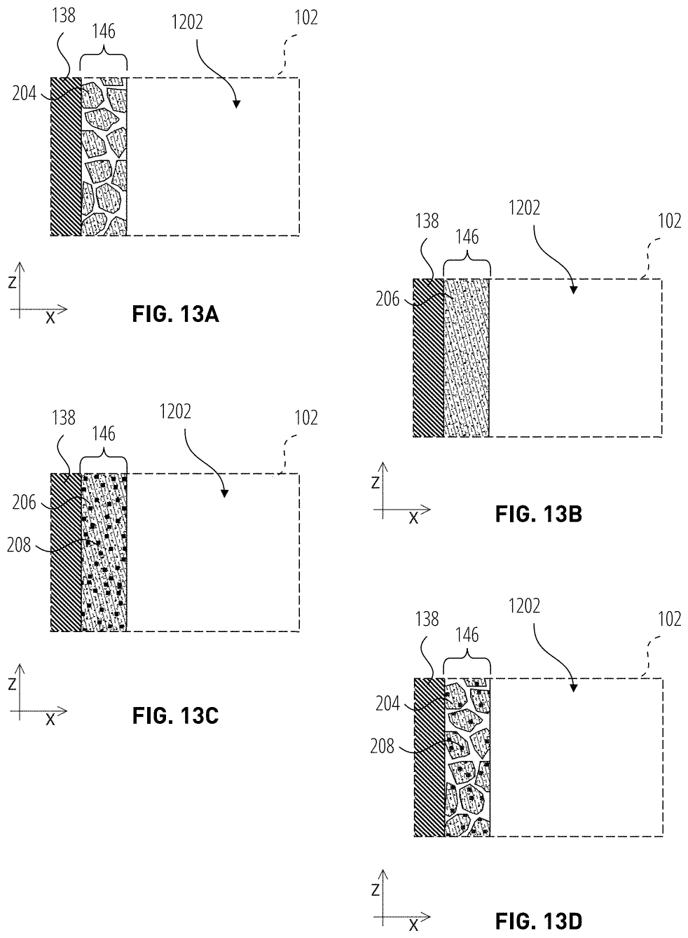

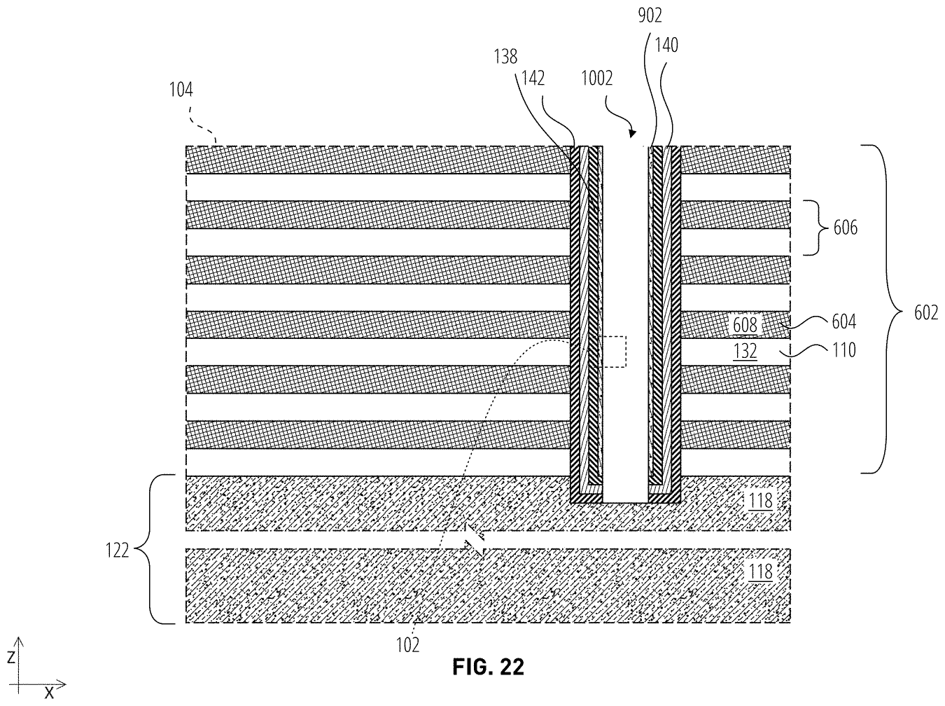

FIG. 13A through FIG. 13D are enlarged illustrations of box 102 of FIG. 22, wherein FIG. 13A illustrates the stage of FIG. 22 in accordance with FIG. 2A, FIG. 13B illustrates the stage of FIG. 22 in accordance with FIG. 2B, FIG. 13C illustrates the stage of FIG. 22 in accordance with FIG. 2C, and FIG. 13D illustrates the stage of FIG. 22 in accordance with FIG. 2D;

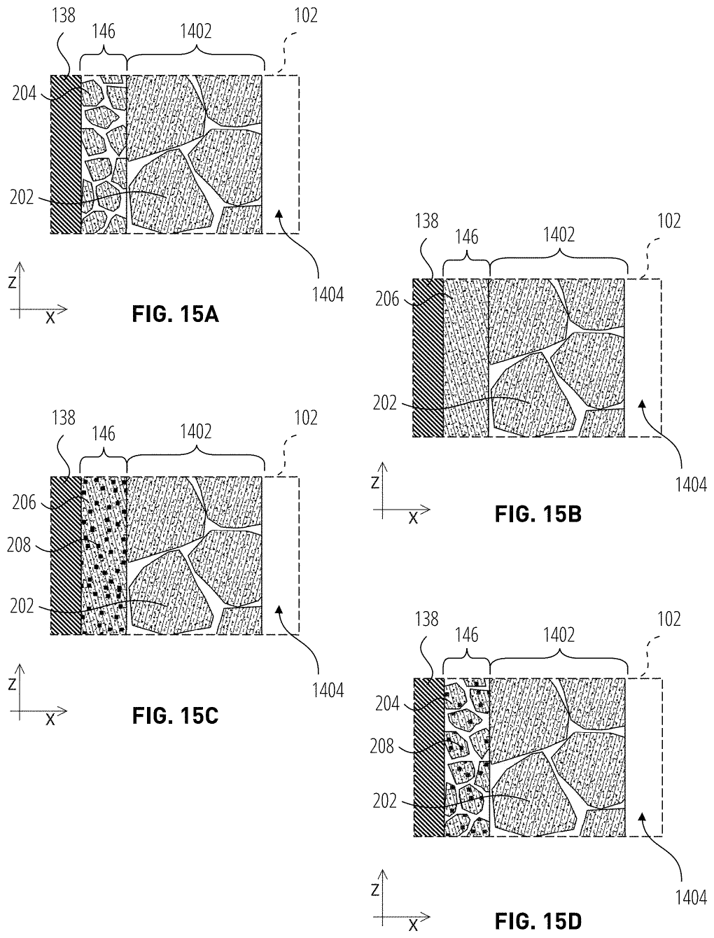

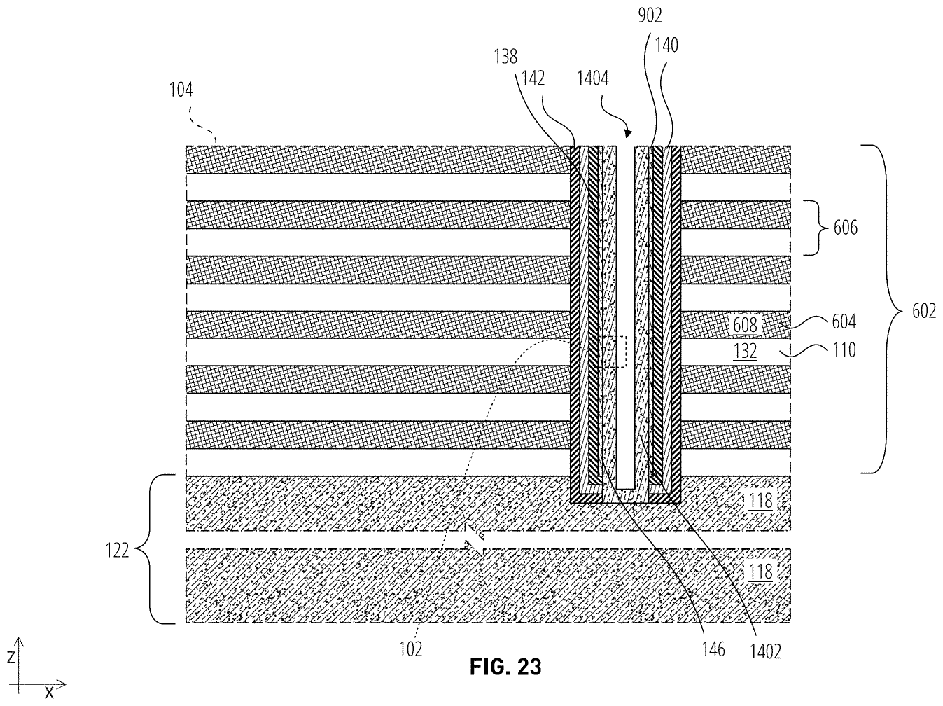

FIG. 15A through FIG. 15D are enlarged illustrations of box 102 of FIG. 23, wherein FIG. 15A illustrates the stage of FIG. 23 in accordance with FIG. 2A, FIG. 15B illustrates the stage of FIG. 23 in accordance with FIG. 2B, FIG. 15C illustrates the stage of FIG. 23 in accordance with FIG. 2C, and FIG. 15D illustrates the stage of FIG. 23 in accordance with FIG. 2D; and

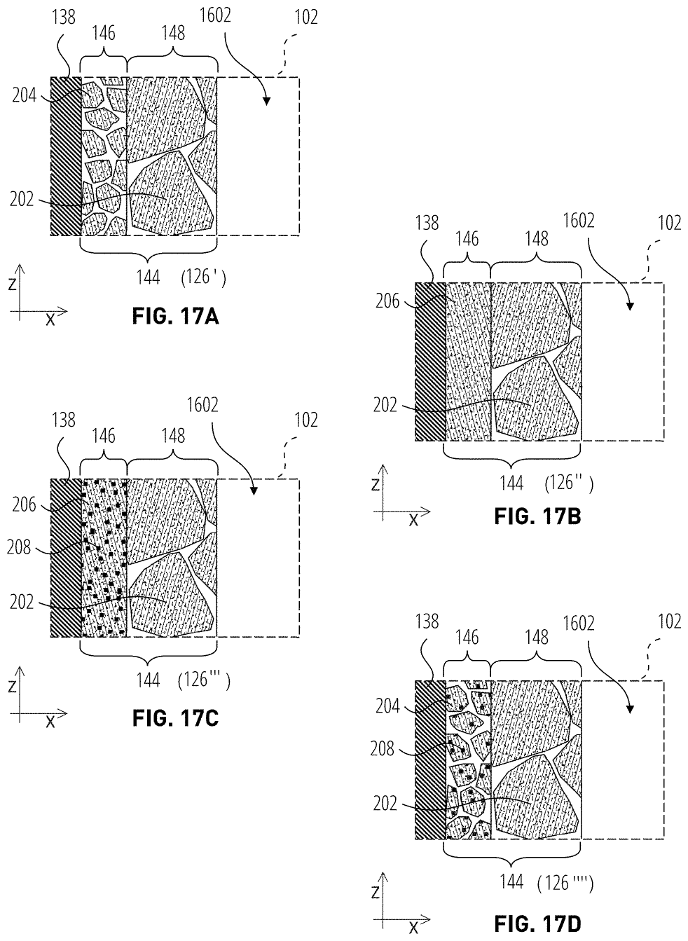

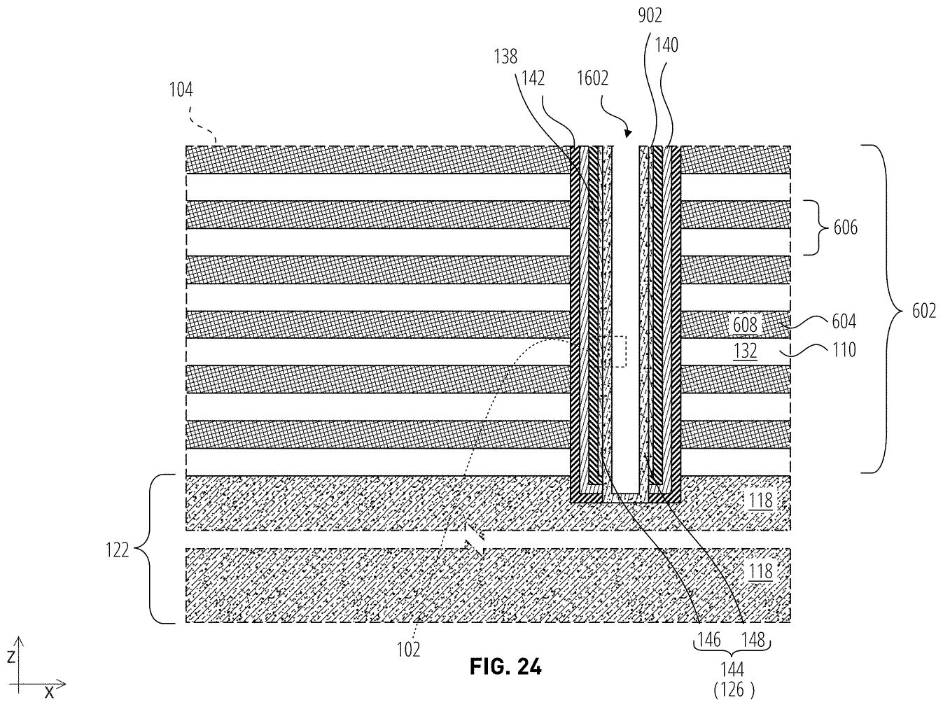

FIG. 17A through FIG. 17D are enlarged illustrations of box 102 of FIG. 24, wherein FIG. 17A illustrates the stage of FIG. 24 in accordance with FIG. 2A, FIG. 17B illustrates the stage of FIG. 24 in accordance with FIG. 2B, FIG. 17C illustrates the stage of FIG. 24 in accordance with FIG. 2C, and FIG. 17D illustrates the stage of FIG. 24 in accordance with FIG. 2D.

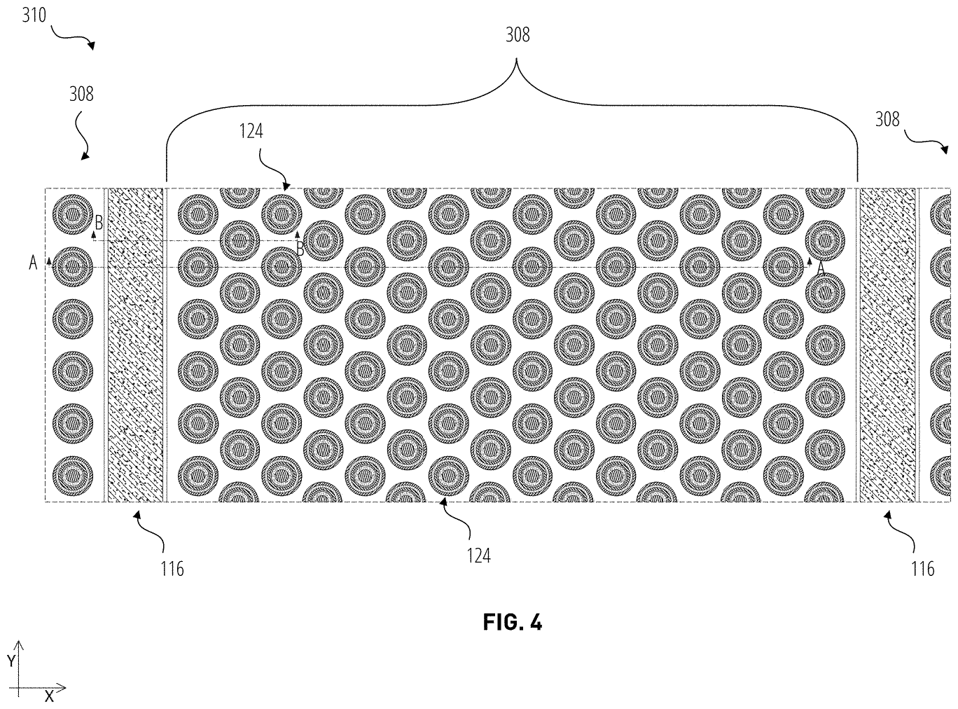

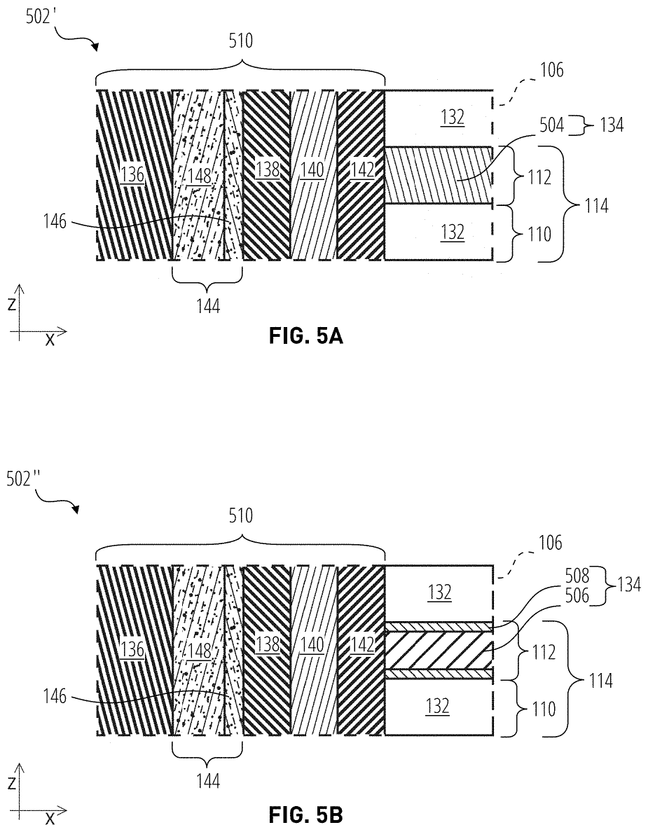

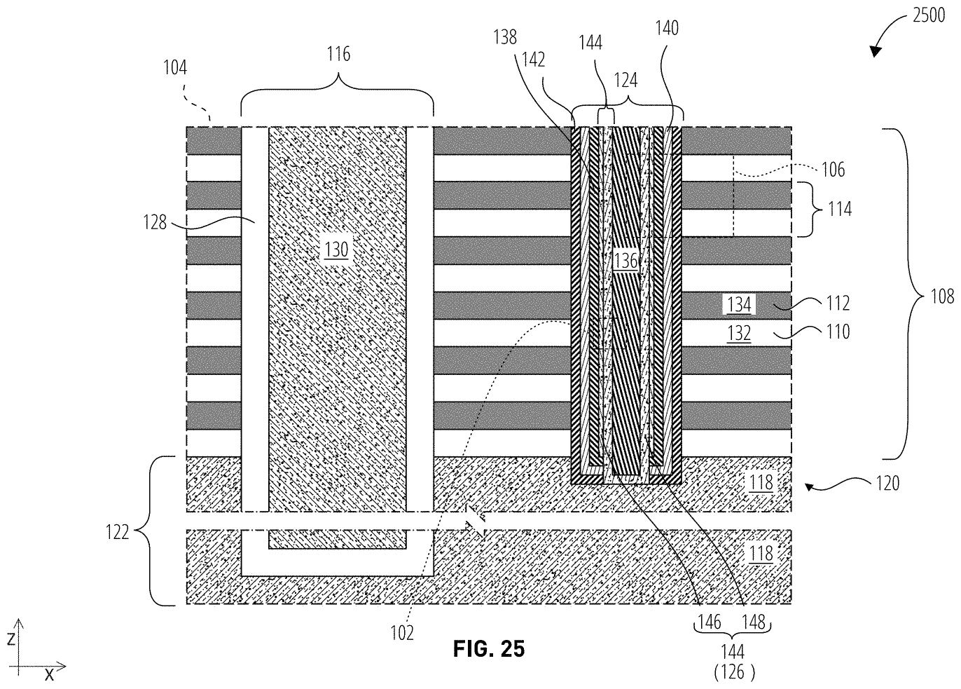

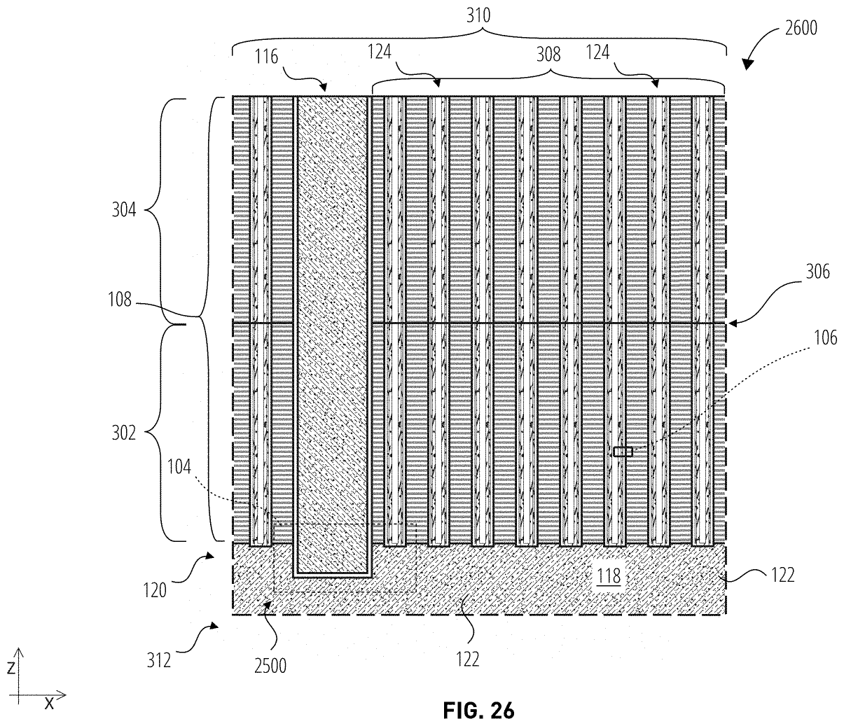

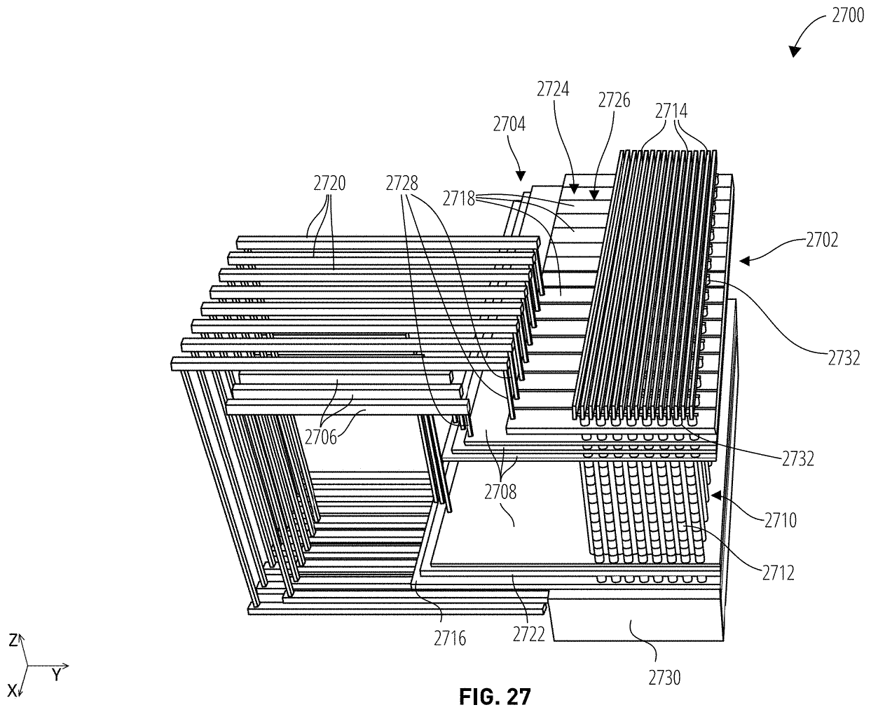

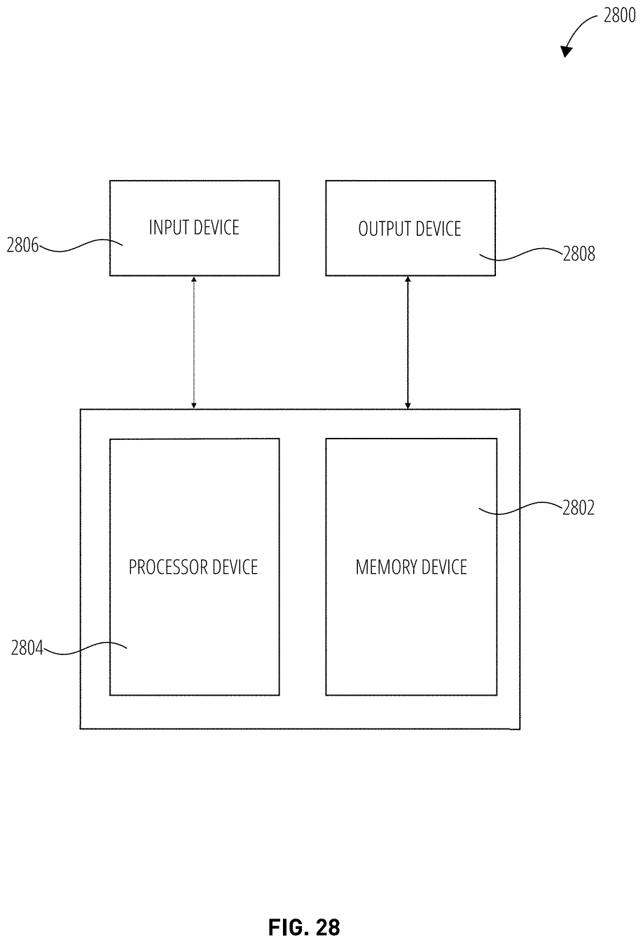

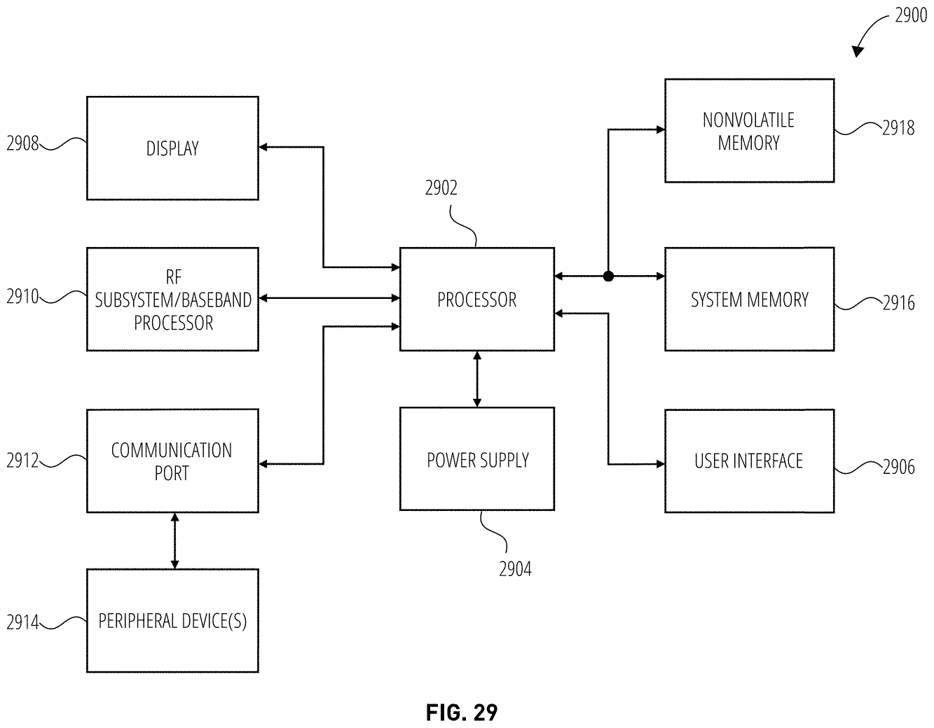

FIG. 25 is a cross-sectional, elevational, schematic illustration of a microelectronic device structure, wherein multiple channel sub-regions of differing microstructures horizontally surround—and an inner sub-region thereof underlays—a central fill material of a pillar structure, in accordance with embodiments of the disclosure. The channel structure sub-regions, and illustrated areas, of any or all of FIG. 2A through FIG. 2D may correspond to, e.g., box 102 of FIG. 25. The memory cells, and illustrated areas, of either or both of FIG. 5A and/or FIG. 5B may correspond to, e.g., box 106 of FIG. 25. FIG. 25 may be a view taken along section line B-B of FIG. 4, in accordance with embodiments of the disclosure.

FIG. 26 is a cross-sectional, elevational, schematic illustration of a microelectronic device structure that may include the microelectronic device structure of FIG. 25 (and, therefore, also any or all of the channel structure sub-regions of FIG. 2A through FIG. 2D and/or either or both of the memory cells 502 of FIG. 5A and/or FIG. 5B, such that the illustration of FIG. 25 may be an enlarged view corresponding to box 104 of FIG. 26), in accordance with embodiments of the disclosure. Moreover, a top, plan, schematic illustration of the microelectronic device structure of FIG. 26 may be that which is illustrated in FIG. 4, with the illustration of FIG. 26 being a view taken along section line A-A of FIG. 4.

FIG. 27 is a partial, cutaway, perspective, schematic illustration of a microelectronic device, in accordance with embodiments of the disclosure.

FIG. 28 is a block diagram of an electronic system, in accordance with embodiments of the disclosure.

FIG. 29 is a block diagram of a processor-based system, in accordance with embodiments of the disclosure.

### DETAILED DESCRIPTION

Structures (e.g., microelectronic device structures), apparatus (e.g., microelectronic devices), and systems (e.g., electronic systems), in accordance with embodiments of the disclosure, include a stack of vertically alternating conductive structures and insulative structures arranged in tiers through which pillars vertically extend. The pillars include channel structures, which may be structured as doped hollow channel (“DHC”) structures, with multiple semiconductor material sub-regions of different microstructures (e.g., different grain sizes, different crystallinity) from one another. An outer sub-region is formed of semiconductor material with relatively small grains or with an amorphous structure. An inner sub-region is formed of semiconductor material with relatively large grains.

In a semiconductor channel structure, grain boundaries—the borders between neighboring grains of material—tend to impact such performance characteristics as electron mobility and electrical current (e.g., “string current”). That is, as electrons travel through a semiconductor channel material, grain boundaries scatter electrons, impeding the electrons' ability to quickly move through the channel structure, between source and drain regions. Electron mobility (μ_{eff})—and therefore string current—drops at each encountered grain boundary. The more grain boundaries in a given volume of channel material, the less the overall effective electron mobility—and string current—exhibited by the channel material during device operations (e.g., read, write, erase). Accordingly, it is contemplated that lessening the amount (e.g., volume, density, area) of grain boundaries in a channel material may increase the electron mobility and string current exhibited by the channel material.

One contemplated solution for decreasing the amount of grain boundaries in a channel material is to increase the size of the grains that compose the channel material. A material with a relatively larger-grain microstructure has a relatively greater volume occupied by the grains themselves, rather than by the grain boundaries. The lower grain boundary amount provides a lower amount of physical impediments (e.g., “traps”) to electron mobility and, therefore, a higher effective electric current (e.g., string current) through the channel material.

Forming a material with large grains may be achieved by forming (e.g., depositing) a relatively thick region of the material. That is, grains tend to grow to a relatively larger size in a relatively thicker deposited material region compared to the grains grown in a relatively thinner deposited material region. The larger grain size may be facilitated by the increased deposited material thickness providing more volume, and therefore more opportunities, for grain boundary mitigation. Furthermore, the larger grain growth reduces the overall system energy. Therefore, depositing a relatively thick region of material tends to form the material with relatively large grains; whereas, depositing a relatively thin region of material tends to form the material with relatively small grains. A relatively thick material region may also promote grain growth—and therefore increased grain size—after thermal treatment (e.g., “reflow” processes).

While large grains may be formed by a thick material deposition, a relatively thin (e.g., less than about 10 nm) wall may be desired for a so-called “doped hollow channel” (“DHC”) structure in a pillar for a memory device. Depositing a channel material this thinly may form small grains and, consequently, a relatively large amount of grain boundaries in the channel material. Contrarily, depositing the channel material to a greater initial thickness—so as to form the material with large grains—and then thinning to the final desired thickness, may form the channel structure (e.g., the DHC structure) with large grains in a relatively thin structure. Accordingly the deposit-thick-then-thin process may form a thin channel structure with a large-grain microstructure.

Though a larger-grain material has a relatively lower grain boundary amount compared to a smaller-grain material of the same material thickness, the grain boundaries in the larger-grain material tend to be relatively less complex than those in a smaller-grain material of the same thickness. A less complex grain boundary provides a more direct pathway for chemical species to traverse into or through the material. In fabricating pillars, processing acts subsequent to formation of the channel material—such as oxygen-based material-removal or oxidation acts—may expose the channel material (e.g., an inner surface of the channel material) to such chemical species (e.g., oxygen). The likelihood of such chemical species traversing wholly through the thickness of the channel material may be generally more likely in a large-grain channel material than in a small-grain or non-grain (e.g., amorphous) channel material. Should the chemical species successfully traverse through the channel structure—from an inner surface to an outer surface—the chemical species may cause chemical damage and/or roughness at the outer surface where the channel material interfaces with a neighboring material (e.g., a tunneling dielectric material). The chemical damage and/or surface roughness may increase local electric fields, which may cause data loss in nearby memory material of the pillar.

Accordingly, a channel material of a larger-grain semiconductor material may be associated with data retention problems in the memory device, compared to a channel material of a smaller-grain semiconductor material. However, as noted above, a channel material of a smaller-grain semiconductor material may be associated with a lower string current (e.g., due to the grain boundary traps impeding electron mobility) compared to a channel material of a larger-grain semiconductor material. Therefore, as semiconductor channel structures are designed to be thinner and thinner, to accommodate device scaling, the concern of designing and forming pillars with sufficient string current and data retention performance characteristics is likely to become even more challenging.

In accordance with embodiments of the disclosure, a hollow channel structure is formed to include multiple sub-regions having different microstructures. An inner sub-region is formed of and includes a relatively large-grain microstructure, and an outer sub-region is formed of and includes a relatively small-grain or non-grain (e.g., amorphous) microstructure. The larger grains of the inner sub-region—and the lower density of grain boundaries—facilitate electron mobility (and string current) in the channel structure. The smaller grains or amorphous microstructure of the outer sub-region inhibits the travel of chemical species (e.g., oxygen). That is, the smaller-grain or amorphous microstructure material has either more complex grain boundary pathways—relative to the larger-grain microstructure material—or substantially no defined grain boundary pathways. This impedes the chemical species' ability to traverse across the smaller-grain or amorphous material. Less chemical species may, therefore, reach an outer surface of the channel structure and interface with a neighboring material (e.g., a tunneling dielectric material). By inhibiting the chemical species from reaching the outer surface and interface, chemical damage and surface roughening at the outer surface or interface may be avoided or lessened. Avoiding or lessening this damage and/or roughening may avoid or lessen local electric fields and, therefore, facilitate data retention in nearby memory material of the pillar. Accordingly, the multiple sub-regions with different microstructures (e.g., large-grain/small-grain or grain/non-grain microstructures) provides a hollow channel structure that may be formed to have a thin (e.g., less than about 10 nm transverse thickness), hollow structure.

As used herein, the terms “inner” and “outer,” and the like, are spatially-relative terms that may be used for ease of description to describe one element's or feature's relationship to another element(s) or feature(s) as illustrated in the figures. An element or feature described as “inner” is relatively nearer a center of a reference structure than an element or feature described as “outer.” Accordingly, an “inner sub-region,” of a structure having multiple sub-regions, may be disposed nearer an axial centerline of the structure than an “outer sub-region” of the structure.

As used herein, the term “trace species” means and includes an element or elements, such as atoms or molecules, present—on or within a volume of another material(s) —in a trace amount, e.g., an atomic fraction (atoms of the trace species relative to atoms of other species within the other material(s)) of from about 1×10⁻⁸ to about 1×10⁻¹, e.g., from about (0.001 to about 0.01). The trace amount may be determined based on a concentration within a total volume of material(s) of an identified characteristic (e.g., semiconductor material(s)) of a structure (e.g., a channel structure) or region of a structure (e.g., a sub-region of a channel structure), though the trace species may be, e.g., dispersed throughout the volume (e.g., of the structure or of the region of the structure) or concentrated in a portion thereof or at or near one or more surfaces thereof. In some embodiments, a “trace species” may be present in a concentration of less than about 10²² atoms (of the trace species) per cm³ of material (e.g., semiconductor material) that comprises the trace species.

As used herein, the terms “opening,” “trench,” “slit,” “recess,” and “void” mean and include a volume extending through or into at least one structure or at least one material, leaving a gap in that at least one structure or at least one material, or a volume extending between structures or materials, leaving a gap between the structures or materials. Unless otherwise described, an “opening,” “trench,” “slit,” and/or “recess” is not necessarily empty of material. That is, an “opening,” “trench,” “slit,” or “recess” is not necessarily void space. An “opening,” “trench,” “slit,” or “recess” formed in or between structures or materials may comprise structure(s) or material(s) other than that in or between which the opening is formed. And, structure(s) or material(s) “exposed” within an opening, trench, slit, or recess is/are not necessarily in contact with an atmosphere or non-solid environment. Structure(s) or material(s) “exposed” within an opening, trench, slit, or recess may be adjacent or in contact with other structure(s) or material(s) that is/are disposed within the opening, trench, slit, or recess. In contrast, unless otherwise described, a “void” may be substantially or wholly empty of material. A “void” formed in or between structures or materials may not comprise structure(s) or material(s) other than that in or between which the “void” is formed. And, structure(s) or material(s) “exposed” within a “void” may be in contact with an atmosphere or non-solid environment.

As used herein, the terms “trench” and “slit” mean and include an elongate opening, while the terms “opening,” “recess,” and “void” may include one or more of an elongate opening, an elongate recess, an elongate void, a non-elongate opening, a non-elongate recess, or a non-elongate void.

As used herein, the term “elongate” means and includes a geometric shape including a dimension (e.g., a length, as defined below) in a first horizontal direction (e.g., a longitudinal direction, as defined below) that is greater than an additional dimension (e.g., a width, as defined below) in a second horizontal direction (e.g., a lateral direction, as defined below) orthogonal to the first horizontal direction.

As used herein, the terms “substrate” and “base structure” mean and include a base material or other construction upon which components, such as those within memory cells, are formed. The substrate or base structure may be a semiconductor substrate, a base semiconductor material on a supporting structure, a metal electrode, or a semiconductor substrate having one or more materials, structures, or regions formed thereon. The substrate may be a conventional silicon substrate or other bulk substrate including a semiconductive material. As used herein, the term “bulk substrate” means and includes not only silicon wafers, but also silicon-on-insulator (“SOT”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” or “base structure” in the following description, previous process stages may have been utilized to form materials, structures, or junctions in the base semiconductor structure, base structure, or other foundation.

As used herein, the term “insulative,” when used in reference to a material or structure, means and includes a material or structure that is electrically insulating. An “insulative” material or structure may be formed of and include one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiₓN_{y})), at least one dielectric oxynitride material (e.g., a silicon oxynitride (SiOₓN_{y})), at least one dielectric carboxynitride material (e.g., a silicon carboxynitride (SiOₓC_{z}N_{y})), and/or air. Formulae including one or more of “x,” “y,” and/or “z” herein (e.g., SiOₓ, AlOₓ, HfOₓ, NbOₓ, TiOₓ, SiₓN_{y}, SiOₓN_{y}, SiOₓC_{z}N_{y}) represent a material that contains an average ratio of “x” atoms of one element, “y” atoms of another element, and/or “z” atoms of an additional element (if any), respectively, for every one atom of another element (e.g., Si, Al, Hf, Nb, Ti). As the formulae are representative of relative atomic ratios and not strict chemical structure, an insulative material or insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “sacrificial,” when used in reference to a material or structure, means and includes a material or structure that is formed during a fabrication process but which is removed (e.g., substantially removed) prior to completion of the fabrication process.

As used herein, the term “horizontal” means and includes a direction that is parallel to a primary surface of the substrate on which the referenced material or structure is located. The “width” and “length” of a respective material or structure may be defined as dimensions in a horizontal plane. With reference to the figures, the “horizontal” direction may be perpendicular to an indicated “Z” axis, may be parallel to an indicated “X” axis, and may be parallel to an indicated “Y” axis.

As used herein, the term “lateral” means and includes a direction in a horizontal plane parallel to a primary surface of the substrate on which a referenced material or structure is located and substantially perpendicular to a “longitudinal” direction. The “width” of a respective material or structure may be defined as a dimension in the lateral direction of the horizontal plane. With reference to the figures, the “lateral” direction may be parallel to an indicated “X” axis, may be perpendicular to an indicated “Y” axis, and may be perpendicular to an indicated “Z” axis.

As used herein, the term “longitudinal” means and includes a direction in a horizontal plane parallel to a primary surface of the substrate on which a referenced material or structure is located, and substantially perpendicular to a “lateral” direction. The “length” of a respective material or structure may be defined as a dimension in the longitudinal direction of the horizontal plane. With reference to the figures, the “longitudinal” direction may be parallel to an indicated “Y” axis, may be perpendicular to an indicated “X” axis, and may be perpendicular to an indicated “Z” axis.

As used herein, the term “vertical” means and includes a direction that is perpendicular to a primary surface of the substrate on which a referenced material or structure is located. The “height” of a respective material or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the term “width” means and includes a dimension, along an indicated “X” axis in a horizontal plane (e.g., at a certain elevation, if identified), defining a maximum distance, along such “X” axis in the horizontal plane, of the material or structure in question. For example, a “width” of a structure that is at least partially hollow, or that is at least partially filled with one or more other material(s), is the horizontal dimension between outermost edges or sidewalls of the structure, such as an outer “X”-axis diameter for a hollow or filled, cylindrical structure.

As used herein, the term “length” means and includes a dimension, along an indicated “Y” axis in a horizontal plane (e.g., at a certain elevation, if identified), defining a maximum distance, along such “Y” axis in the horizontal plane, of the material or structure in question. For example, a “length” of a structure that is at least partially hollow, or that is at least partially filled with one or more other material(s), is the horizontal dimension between outermost edges or sidewalls of the structure, such as an outer “Y”-axis diameter for a hollow or filled, cylindrical structure.

As used herein, the terms “thickness” or “thinness” are spatially relative terms that mean and include a dimension in a straight-line direction that is normal to the closest surface of an immediately adjacent material or structure that is of a different composition or that is otherwise distinguishable from the material or structure whose thickness, thinness, or height is discussed.

As used herein, the term “between” is a spatially relative term used to describe the relative disposition of one material, structure, or sub-structure relative to at least two other materials, structures, or sub-structures. The term “between” may encompass both a disposition of one material, structure, or sub-structure directly adjacent the other materials, structures, or sub-structures and a disposition of one material, structure, or sub-structure indirectly adjacent to the other materials, structures, or sub-structures.

As used herein, the term “proximate” is a spatially relative term used to describe disposition of one material, structure, or sub-structure near to another material, structure, or sub-structure. The term “proximate” includes dispositions of indirectly adjacent to, directly adjacent to, and internal to.

As used herein, the term “neighboring,” when referring to a material or structure, is a spatially relative term that means and refers to a next, most proximate material or structure of an identified composition or characteristic. Materials or structures of other compositions or characteristics than the identified composition or characteristic may be disposed between one material or structure and its “neighboring” material or structure of the identified composition or characteristic. For example, a structure of material X “neighboring” a structure of material Y is the first material X structure, e.g., of multiple material X structures, that is most proximate to the particular structure of material Y. The “neighboring” material or structure may be directly adjacent or indirectly adjacent the structure or material of the identified composition or characteristic.

As used herein, the term “consistent”—when referring to a parameter, property, or condition of one structure, material, feature, or portion thereof in comparison to the parameter, property, or condition of another such structure, material, feature, or portion of such same aforementioned structure, material, or feature—is a relative term that means and includes the parameter, property, or condition of the two such structures, materials, features, or portions being equal, substantially equal, or about equal, at least in terms of respective dispositions of such structures, materials, features, or portions. For example, two structures having “consistent” thickness as one another may each define a same, substantially same, or about the same thickness at X lateral distance from a feature, despite the two structures being at different elevations along the feature. As another example, one structure having a “consistent” width, length, and/or diameter may have two portions that each define a same, substantially same, or about the same width, length, and/or diameter, respectively, at elevation Y1 of such structure as at elevation Y2 of such structure.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, the terms “on” or “over,” when referring to an element as being “on” or “over” another element, are spatially relative terms that mean and include the element being directly on top of, adjacent to (e.g., laterally adjacent to, horizontally adjacent to, longitudinally adjacent to, vertically adjacent to), underneath, or in direct contact with the other element. It also includes the element being indirectly on top of, adjacent to (e.g., laterally adjacent to, horizontally adjacent to, longitudinally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, any spatially relative terms used in this disclosure are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “level” and “elevation” are spatially relative terms used to describe one material's or feature's relationship to another material(s) or feature(s) as illustrated in the figures, using—as a reference point—the lowest illustrated surface of the structure that includes the materials or features. As used herein, a “level” and an “elevation” are each defined by a horizontal plane parallel to a primary surface of the substrate or base structure on or in which the structure (that includes the materials or features) is formed. “Lower levels” and “lower elevations” are relatively nearer to the bottom-most illustrated surface of the respective structure, while “higher levels” and “higher elevations” are relatively further from the bottom-most illustrated surface of the respective structure. Unless otherwise specified, any spatially relative terms used in this disclosure are intended to encompass different orientations of the materials in addition to the orientation as depicted in the figures. For example, the materials in the figures may be inverted, rotated, etc., with the “upper” levels and elevations then illustrated proximate the bottom of the page and the “lower” levels and elevations then illustrated proximate the top of the page.

As used herein, the terms “comprising,” “including,” “having,” and grammatical equivalents thereof are inclusive, open-ended terms that do not exclude additional, unrecited elements or method steps. These terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a composition (e.g., gas) described as “comprising,” “including,” and/or “having” a species may be a composition that, in some embodiments, includes additional species as well and/or a composition that, in some embodiments, does not include any other species.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” means and includes any and all combinations of one or more of the associated listed items.

As used herein, the singular forms “a,” “an,” and “the” are intended to include the plural forms as well, unless the context clearly indicates otherwise.

As used herein, a “(s)” at the end of a term means and includes the singular form of the term and/or the plural form of the term, unless the context clearly indicates otherwise.

As used herein, the terms “configured” and “configuration” mean and refer to a size, shape, material composition, orientation, and arrangement of a referenced material, structure, assembly, or apparatus so as to facilitate a referenced operation or property of the referenced material, structure, assembly, or apparatus in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded. Thus, the materials, features, and structures illustrated in the figures are schematic in nature and their shapes are not intended to illustrate the precise shape of a material, feature, or structure and do not limit the scope of the present claims. A figure representing an enlarged view of a portion of another figure is not necessarily to scale. For example, one or more features of an enlarged view may be illustrated relatively smaller than a to-scale enlargement would provide, for ease of illustration and view.

The following description provides specific details, such as material types and processing conditions, to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

In referring to the drawings, like numerals refer to like components throughout. The drawings are not necessarily drawn to scale.

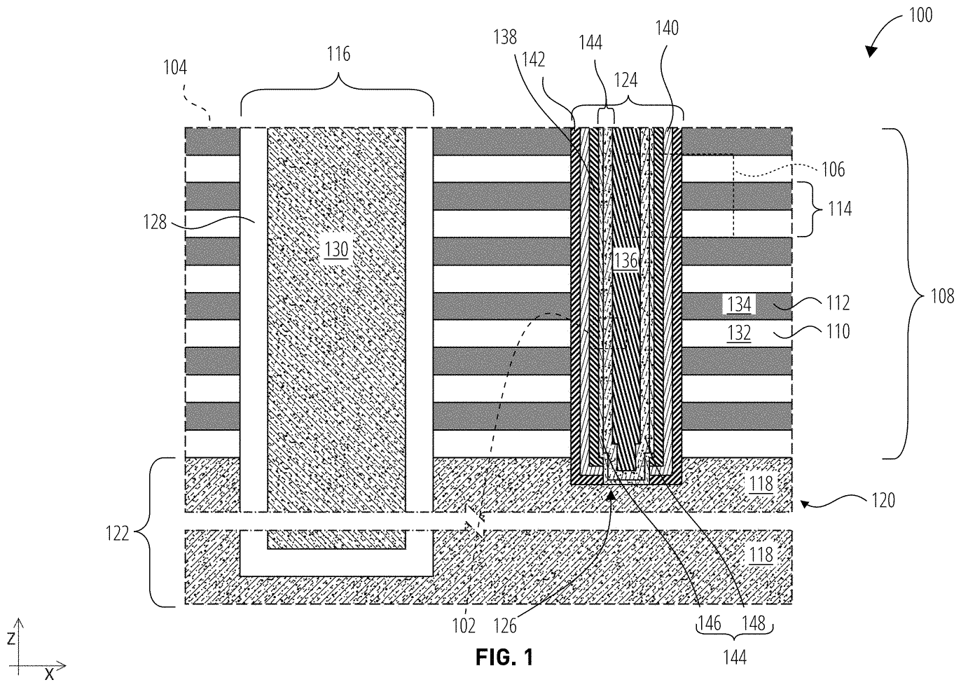

With reference to FIG. 1, illustrated, in elevational cross-sectional view, is a microelectronic device structure 100 that includes a stack structure 108 of vertically alternating (e.g., vertically interleaved) insulative structures 110 and conductive structures 112 arranged in tiers 114. Slit structures 116 extend through the stack structure 108 and to or into a doped material 118 of a source region 120 of a base structure 122. The slit structures 116 divide the stack structure 108 into blocks, as further discussed below. Pillars 124, including channel structures 126, also extend through the stack structure 108 and to and/or into the doped material 118 of the base structure 122.

The base structure 122 may be formed of and include, for example, one or more semiconductor materials (e.g., polycrystalline silicon (polysilicon)). Adjacent the stack structure 108, the semiconductor material may be doped (e.g., the doped material 118) to provide a source region 120 adjacent a lower end of the pillars 124. The doped material 118 may be formed of and include, for example, a semiconductor material (e.g., polysilicon) doped with one or more P-type conductivity chemical species (e.g., one or more of boron, aluminum, and gallium) or one or more N-type conductivity chemical species (e.g., one or more of arsenic, phosphorous, and antimony).

The slit structure 116 may include an insulative liner 128 (e.g., formed of and including one or more insulative material(s)) and a nonconductive fill material 130 (e.g., any one or more of the aforementioned insulative material(s) and/or a semiconductive material, such as polysilicon). In some embodiments, sidewalls of the conductive structures 112 are laterally recessed, relative to the insulative structures 110, along the slit structure 116. In such embodiments, the insulative liner 128 may laterally extend in correspondence with the lateral recesses of the conductive structures 112.

In the stack structure 108, the insulative structures 110 may be formed of and include at least one insulative material 132, such as a dielectric oxide material (e.g., silicon dioxide). In this and other embodiments described herein, the insulative material 132 of the insulative structures 110 may be substantially the same as or different than other insulative material(s) of the microelectronic device structure 100.

The conductive structures 112 of the stack structure 108 may be formed of and include one or more conductive materials 134, such as one or more of: at least one metal (e.g., one or more of tungsten, titanium, nickel, platinum, rhodium, ruthenium, iridium, aluminum, copper, molybdenum, silver, gold), at least one alloy (e.g., an alloy of one or more of the aforementioned metals), at least one metal-containing material that includes one or more of the aforementioned metals (e.g., metal nitrides, metal silicides, metal carbides, metal oxides, such as a material including one or more of titanium nitride (TiN), tantalum nitride (TaN), tungsten nitride (WN), titanium aluminum nitride (TiAlN), iridium oxide (IrOₓ), ruthenium oxide (RuOₓ), alloys thereof), at least one conductively-doped semiconductor material (e.g., conductively-doped silicon, conductively-doped germanium, conductively-doped silicon germanium), polysilicon, and at least one other material exhibiting electrical conductivity. In some embodiments, the conductive structures 112 include at least one of the aforementioned conductive materials, along with at least one additional conductive material formed as a liner.

In some embodiments, one or more of the conductive structures 112 neighboring the source region 120 of the doped material 118 may be configured as gate-induced drain leakage (“GIDL”) region(s), such as a source-gate select device (e.g., a SGS device). In some such embodiments, one or more conductive structures 112 atop the stack structure 108 may also be configured as GIDL region(s), such as a drain-gate select device (e.g., a SGD device).

In the elevations of the stack structure 108 (e.g., elevations above the source region 120), the pillars 124 are horizontally surrounded by the materials of the tiers 114 of the insulative structures 110 and the conductive structures 112. The channel structure 126 may be interposed horizontally between an insulative material 136—forming a core of the pillar 124—and the tiers 114 of the stack structure 108. Portions of the channel structure 126 may also be disposed vertically beneath the insulative material 136.

The insulative material 136 (e.g., at the core of the pillar 124) may be formed of and include an insulative material such as, for example, phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide, a nitride material, (e.g., silicon nitride (Si₃N₄)), an oxynitride (e.g., silicon oxynitride), a dielectric carbon nitride material (e.g., silicon carbon nitride (SiCN)), a dielectric carboxynitride material (e.g., silicon carboxynitride (SiOCN)), an insulative gas (e.g., air), or combinations thereof. In some embodiments, the insulative material 136 comprises silicon dioxide.

In addition to the insulative material 136 and the channel structure 126, the pillars 124 also include cell materials interposed horizontally between the channel structure 126 and the tiers 114 of the stack structure 108. The cell materials may include a tunnel dielectric material 138 (also referred to as a “tunneling dielectric material”), which may be horizontally adjacent the channel structure 126; a memory material 140, which may be horizontally adjacent the tunnel dielectric material 138; and a dielectric blocking material 142 (also referred to as a “charge blocking material”), which may be horizontally adjacent the memory material 140. In some embodiments, a dielectric barrier material is also horizontally interposed (e.g., directly horizontally interposed) between the dielectric blocking material 142 and the tiers 114 of the stack structure 108. The cell materials—including the tunnel dielectric material 138, the memory material 140, the dielectric blocking material 142, and, if present, the dielectric blocking material 142—may also extend to and/or into the doped material 118 of the base structure 122. The tunnel dielectric material 138, the memory material 140, the dielectric blocking material 142, and, if present, the dielectric blocking material 142 may not extend across a base of the pillars 124 such that these materials may not vertically underlay the insulative material 136.

The tunnel dielectric material 138 may be formed of and include a dielectric material through which charge tunneling can be performed under suitable electrical bias conditions, such as through hot-carrier injection or by Fowler-Nordheim tunneling induced charge transfer. The tunnel dielectric material 138 may be formed of and include one or more of silicon oxide, silicon nitride, silicon oxynitride, dielectric metal oxides (e.g., aluminum oxide and hafnium oxide), dielectric metal oxynitride, dielectric metal silicates, alloys thereof, and/or combinations thereof. In some embodiments, the tunnel dielectric material 138 comprises silicon dioxide or silicon oxynitride.

The memory material 140 may comprise a charge trapping material or a conductive material. The memory material 140 may be formed of and include one or more of silicon nitride, silicon oxynitride, polysilicon (e.g., doped polysilicon), a conductive material (e.g., tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), a semiconductive material polycrystalline or amorphous semiconductor material including at least one elemental semiconductor element or at least one compound semiconductor material, conductive nanoparticles (e.g., ruthenium nanoparticles), metal dots. In some embodiments, the memory material 140 comprises silicon nitride.

The dielectric blocking material 142 may be formed of and include one or more dielectric materials, such as, for example, one or more of an oxide (e.g., silicon dioxide), a nitride (e.g., silicon nitride), an oxynitride (e.g., silicon oxynitride), or another material. The material(s) of the dielectric blocking material 142 may be formed as one or more distinctive material regions (e.g., sub-regions, layers). In some embodiments, the dielectric blocking material 142 comprises a single material region, which may be formed of and include silicon oxynitride. In other embodiments, the dielectric blocking material 142 comprises a structure configured as an oxide-nitride-oxide (ONO) structure, with a series of material regions (e.g., sub-regions, layers) formed of and including, respectively, an oxide (e.g., silicon dioxide), a nitride (e.g., silicon nitride), and an oxide again (e.g., silicon dioxide).

In some embodiments, the tunnel dielectric material 138, the memory material 140, and the dielectric blocking material 142 together may form a structure configured to trap a charge, such as, for example, an oxide-nitride-oxide (ONO) structure. In some such embodiments, the tunnel dielectric material 138 comprises silicon dioxide, the memory material 140 comprises silicon nitride, and the dielectric blocking material 142 comprises silicon dioxide.

In embodiments including a dielectric barrier material, it may be formed of and include one or more of a metal oxide (e.g., one or more of aluminum oxide, hafnium oxide, zirconium oxide, lanthanum oxide, yttrium oxide, tantalum oxide, gadolinium oxide, niobium oxide, titanium oxide), a dielectric silicide (e.g., aluminum silicide, hafnium silicate, zirconium silicate, lanthanum silicide, yttrium silicide, tantalum silicide), and a dielectric nitride (e.g., aluminum nitride, hafnium nitride, lanthanum nitride, yttrium nitride, tantalum nitride).

The channel structure 126 includes multiple sub-regions of channel material 144, with at least one such sub-region of channel material 144 having a different microstructure than at least one other sub-region of channel material 144. In some embodiments, the channel structure 126 includes only two sub-regions with an outer sub-region 146 directly adjacent an inner sub-region 148. In other embodiments, at least one additional sub-region is interposed between the outer sub-region 146 and the inner sub-region 148.

In combination, the sub-regions (e.g., the outer sub-region 146 and the inner sub-region 148) of the channel structure 126 form the channel structure 126, which may be formed as a relatively-thin hollow structure horizontally surrounding the insulative material 136 of the pillar 124. The wall of the channel structure 126 may have a total thickness (e.g., between an interface with the insulative material 136 and an interface with the tunnel dielectric material 138) of less than about 10 nm (e.g., about 6 nm to about 10 nm).

An outer sub-region 146 of the channel structure 126 may be configured to be as thin as possible while still inhibiting chemical species (e.g., oxygen) from traversing through the outer sub-region 146 to the outer surface of the channel structure 126 (e.g., the surface of the channel structure 126 that interfaces with the tunnel dielectric material 138). The outer sub-region 146 may be no thicker than the inner sub-region 148, such that the outer sub-region 146 may compose up to about half the thickness (e.g., less than about 50% of the total thickness, less than about 40% of the total thickness, less than about 30% of the total thickness, less than about 20% of the total thickness) of the channel structure 126. In some embodiments, the thickness of the outer sub-region 146 (e.g., the average horizontal dimension, in elevations of the stack structure 108 that include conductive structures 112 configured as word lines, between an interface with the tunnel dielectric material 138 and an interface with the inner sub-region 148) may be in a range from about 10% to about 40% of the total thickness of the wall of the channel structure 126. In some embodiments, the thickness of the outer sub-region 146 may be about 5 nm or less (e.g., about 4 nm or less, about 3 nm or less).

The inner sub-region 148 may compose at least about half the thickness (e.g., greater than about 50% of the total thickness, greater than about 60% of the total thickness, greater than about 70% of the total thickness, greater than about 80% of the total thickness) of the channel structure 126. In some embodiments, the thickness of the inner sub-region 148 (e.g., the average horizontal dimension, in elevations of the stack structure 108 that include conductive structures 112 configured as word lines, between an interface with the outer sub-region 146 and the insulative material 136) may be in a range from about 60% to about 90% of the total thickness of the wall of the channel structure 126. In some embodiments, the thickness of the inner sub-region 148 may be about 3 nm or greater (e.g., about 4 nm or greater, about 5 nm or greater).

The channel material 144 of the sub-regions (e.g., the outer sub-region 146, the inner sub-region 148, and any intermediate sub-regions, if present) may be formed of and include one or more of at least one semiconductor material (at least one elemental semiconductor material, such as polycrystalline silicon; at least one III-V compound semiconductor material, at least one II-VI compound semiconductor material, at least one organic semiconductor material, GaAs, InP, GaP, GaN, other semiconductor materials); and at least one an oxide semiconductor material. The channel material 144 of each sub-region may be selected or otherwise formulated to have high mobility (e.g., a semiconductor material including one or more of doped polysilicon, germanium (Ge), silicon germanium (SiGe), and gallium arsenide (GaAs)). In some embodiments, the channel material 144 of each sub-region includes a doped semiconductor material. In some embodiments, all of the sub-regions of the channel structure 126 may comprise the channel material 144 with a substantially same chemical composition, but with a difference in microstructure. In other embodiments, one or more of the sub-regions of the channel structure 126 may comprise any one or more of the channel materials 144 of a different chemical composition than the channel material 144 (or channel materials 144) of one or more other sub-regions of the channel structure 126.

The channel material 144 of at least one of the sub-regions of the channel structure 126 exhibits a different microstructure than the channel material 144 of at least one other of the sub-regions. As used herein, a “different microstructure” means and includes a difference in average grain size, a difference in grain boundary amount (e.g., volume of grain boundary per volume of channel material 144), a difference in grain boundary complexity (e.g., considering the number, angle, and frequency of deviations of a grain boundary pathway from an otherwise straight-line pathway between interior and exterior surfaces of the sub-region), a difference in crystallographic orientation, or any combination thereof. The channel material 144 may be formed or otherwise structured so that the outer sub-region 146 has—in comparison to the inner sub-region 148—a relatively smaller grain size or a lack of exhibited grain structure, a relatively larger grain boundary amount, a relatively more complex grain boundary pathway, a less consistent (e.g., greater varying) crystallographic orientation, or any combination thereof.

With reference to FIG. 2A through FIG. 2D, schematically illustrated—in enlarged view—are a portion of the channel structure 126 of the microelectronic device structure 100 of FIG. 1, with various different microstructures in the sub-regions of the channel material 144, in accordance with various embodiments of the disclosure.

In some embodiments, the channel structure 126 of FIG. 1 is formed as a channel structure 126′ illustrated in FIG. 2A, with the inner sub-region 148 of the channel material 144 (e.g., polysilicon) having large grains 202 and with the outer sub-region 146 of the channel material 144 (e.g., also polysilicon) having small grains 204. As used herein “small grains” of the channel material 144 have an average grain size of less than about 0.01 μm (e.g., less than about 0.005 μm), and “large grains” of the channel material 144 have an average grain size of greater than about 0.01 μm.

In some embodiments, the channel structure 126 of FIG. 1 is formed as a channel structure 126″ illustrated in FIG. 2B, with the inner sub-region 148 of the channel material 144 (e.g., polysilicon) having the large grains 202 and with the outer sub-region 146 of the channel material 144 being an amorphous material 206 (e.g., amorphous channel material 144, such as amorphous silicon). The insulative material 136 may be directly adjacent the inner sub-region 148 and the large grains 202 of the inner sub-region 148.

In some embodiments, the channel structure 126 of FIG. 1 is formed as a channel structure 126′″ illustrated in FIG. 2C, with the inner sub-region 148 of the channel material 144 (e.g., polysilicon) having the large grains 202 and with the outer sub-region 146 of the channel material 144 being an amorphous material 206 (e.g., amorphous channel material 144, such as amorphous silicon) that includes at least one dopant 208 (e.g., carbon atoms). The presence of the dopant 208 may enable or otherwise promote the amorphous nature of the channel material 144 of the outer sub-region 146. The concentration of the dopant 208 may be of at least about 1×10¹⁵ dopant 208 atoms (e.g., carbon atoms) per cm³ of the material of the outer sub-region 146.

In some embodiments, the channel structure 126 of FIG. 1 is formed as a channel structure 126″″ illustrated in FIG. 2D, with the inner sub-region 148 of the channel material 144 (e.g., polysilicon) having the large grains 202 and with the outer sub-region 146 of the channel material 144 having the small grains 204 and with the small grains 204 including the at least one dopant 208 (e.g., carbon atoms). The presence of the dopant 208 may enable or otherwise promote the small-grain structure of the outer sub-region 146. The concentration of the dopant 208 may be of at least about 1×10¹⁵ dopant 208 atoms (e.g., carbon atoms) per cm³ of the material of the outer sub-region 146.

Regardless of the type of difference in microstructure between the inner sub-region 148 and the outer sub-region 146 of the channel structure 126 (FIG. 1), the large grains 202 and lower grain boundary density of the channel material 144 of the inner sub-region 148—in the channel structure 126′ of FIG. 2A, the channel structure 126″ of FIG. 2B, the channel structure 126′″ of FIG. 2C, and the channel structure 126″″ of FIG. 2D—may facilitate electron mobility (and therefore a sufficient string current) through the respective channel structure 126. In contrast, the relatively smaller grains (e.g., the small grains 204 of FIG. 2A and FIG. 2D) or non-grain structure (e.g., the amorphous material 206 of FIG. 2B and FIG. 2C) and increased grain boundary density and complexity of the channel material 144 of the outer sub-region 146—in the channel structure 126′ of FIG. 2A, the channel structure 126″ of FIG. 2B, the channel structure 126′″ of FIG. 2C, and the channel structure 126″″ of FIG. 2D—may inhibit the travel of chemical species (e.g., oxygen) through the outer sub-region 146 to the interface between the channel structure 126 and the tunnel dielectric material 138. That is, the smaller-grained or non-grained outer sub-region 146—having either more complex or substantially no defined grain boundary pathways—may impede a chemical species' ability to traverse the smaller-grained or non-grained outer sub-region 146. Therefore, no or less chemical species may reach the outer surface of the channel material 144 (e.g., during fabrication). By inhibiting the chemical species from reaching the outer surface and interface, chemical damage and surface roughening of the channel material 144 at the outer surface or interface may be avoided or lessened. Avoiding or lessening this damage and/or roughening may avoid or lessen local electric fields and, therefore, facilitate data retention in the nearby memory material 140 (FIG. 1) of the pillar 124 (FIG. 1). Accordingly, by forming the channel structure 126 to include multiple sub-regions of the channel material 144 with different microstructures (e.g., large-grain/small-grain microstructure difference, as in FIG. 2A and FIG. 2D; grain/non-grain microstructures, as in FIG. 2B and FIG. 2C) the channel structure 126 of FIG. 1 may be formed with both sufficient electron mobility (and string current) as well as sufficient data retention in the memory material 140 (and memory cells formed therefrom), even with a thin wall thickness (e.g., less than about 10 nm) of the channel structure 126.

While FIG. 1 illustrates only one (e.g., a single) pillar 124, only one (e.g., a single) slit structure 116, and six (6) tiers 114 of the stack structure 108, the disclosure is not so limiting. For example, a microelectronic device structure in accordance with embodiments of the disclosure may include multiple (e.g., more than one) pillars 124, multiple (e.g., more than one) slit structures 116, and/or a different quantity of the tiers 114 of the stack structure 108.

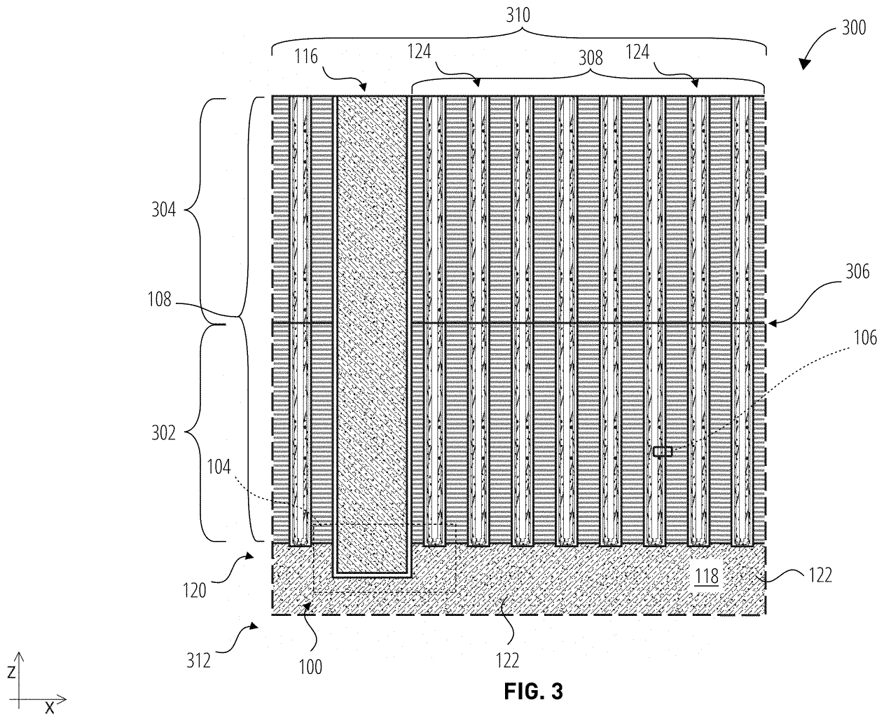

For example, the number (e.g., quantity) of tiers 114 (and conductive structures 112 and insulative structures 110) illustrated in the stack structure 108 of FIG. 1 may constitute only a lower portion of a much taller stack structure—such as illustrated in FIG. 3—that includes additional tiers 114 of the conductive structures 112 and the insulative structures 110. In some embodiments, a number (e.g., quantity) of the tiers 114 of the stack structure 108—and therefore the number (e.g., quantity) of conductive structures 112 in the stack structure 108—is within a range of from thirty-two of the tiers 114 (and of the conductive structures 112) to three-hundred, or more, of the tiers 114 (and of the conductive structures 112). In some embodiments, the stack structure 108 includes one-hundred twenty-eight of the tiers 114 (and of the conductive structures 112). However, the disclosure is not so limited, and the stack structure 108 may include a different number of the tiers 114 (and of the conductive structures 112).

The stack structure 108 may be formed in one or more decks, with each of the decks including a vertically alternating sequence of the insulative structures 110 and the conductive structures 112 arranged in the tiers 114. For example, the microelectronic device structure 100 of FIG. 1 may be only a portion of a microelectronic device structure 300 illustrated in FIG. 3, and the microelectronic device structure 300 may form the stack structure 108 in two parts (e.g., two decks), a lower deck 302 and an upper deck 304. In other embodiments, the stack structure 108 may include more than two decks.

The pillars 124 extend substantially vertically through each of the decks (e.g., the lower deck 302 and the upper deck 304) of the stack structure 108, as well as to or into the doped material 118 (e.g., the source region 120) of the base structure 122. In some embodiments, the materials of the pillars 124 (e.g., the insulative material 136 of the core, the channel material 144 of the multiple sub-regions of the channel structure 126, and the cell materials that include the tunnel dielectric material 138, the memory material 140, and the dielectric blocking material 142 (FIG. 1)) are formed as material regions extending continuously (e.g., seamlessly and/or without distinctive portions) through the upper deck 304 and the lower deck 302 to the doped material 118 of the base structure 122. In other embodiments, the materials of the pillars 124 are separately formed in the upper deck 304 and the lower deck 302 such that separately-formed material regions interface proximate an interdeck portion 306.

In some embodiments, the vertically alternating sequence of the conductive structures 112 and the insulative structures 110 of the tiers 114 (FIG. 1) may be interrupted, proximate the interdeck portion 306, by one or more other structures. For example, at or near the interdeck portion 306 may be an interdeck dielectric region that may be significantly thicker than any individual one of the insulative structures 110 of the tiers 114.

The slit structures 116 extending through the stack structure 108 (e.g., through all decks, including the upper deck 304 and the lower deck 302) divide the microelectronic device structure 300 into blocks 308. Each of the blocks 308 may include an array of the pillars 124, and the sequence of blocks 308 may form a pillar array portion 310 of the microelectronic device structure 300.

Longitudinally adjacent the pillar array portion 310, either with or without intervening features, may be one or more staircase portions that include staircase structure(s) having steps defined by ends (e.g., sidewalls) of at least some of the tiers 114 (FIG. 1). Operative, electrical contacts may be included in the staircase portion to form electrical connection to the various conductive structures 112 (FIG. 1) of the stack structure 108.

The microelectronic device structure 300 may further include additional features. For example, bit lines and bit contacts may be formed above the stack structure 108 (e.g., in the pillar array portion 310) to be in operable communication with the pillars 124 and other electrical features of the microelectronic device structure 300. Additional conductive lines (e.g., conductive routing lines) and contacts may be included above, below, and/or within the stack structure 108 to facilitate electrical communication between two or more features of the microelectronic device structure 300. In some embodiments, CMOS (complementary metal-oxide-semiconductor) circuitry is included in a CMOS region 312 below the source region 120 and the pillars 124 of the pillar array portion 310. In such embodiments, the microelectronic device structure 300 may be characterized as having a so-called “CMOS under Array” (“CuA”) region.

FIG. 4 illustrates, from a top-view perspective, one of the blocks 308 that includes an array of the pillars 124. One block 308 is bordered, at its left and right lateral sides, by one of a pair of the slit structures 116. Additional blocks 308 may be disposed across the slit structures 116. In such a structure as that illustrated in FIG. 4, the pillar array portion 310 of FIG. 3 may be a cross-sectional view taken along section line A-A of FIG. 4, and/or the microelectronic device structure 100 of FIG. 1 may be a cross-sectional view taken alone section line B-B of FIG. 4. The aforementioned staircase portion, may be longitudinally disposed relative to that which is illustrated in FIG. 4.

In the discussions herein, descriptions of one pillar 124 and one channel structure 126 may equally apply to any or all of the pillars 124 and the channel structures 126 of one or more blocks 308 of a microelectronic device structure of any embodiment of this disclosure (e.g., the microelectronic device structure 100 of FIG. 1, the microelectronic device structure 300 of FIG. 3). Accordingly, some or all of the pillars 124 may have substantially the same materials and structures. For example, any or all of the pillars 124 of a respective block 308 may each include the channel structure 126 (FIG. 1) with the different microstructures of the sub-regions as described above in reference to any or all of FIG. 2A, FIG. 2B, FIG. 2C, and/or FIG. 2D. In some embodiments, all of the pillars 124 of a respective block 308 of the pillar array portion 310 may each include the channel structure 126 with a same configuration of sub-regions of different microstructures (e.g., all pillars 124 including the channel structure 126′ of FIG. 2A, all pillars 124 including the channel structure 126″ of FIG. 2B, all pillars 124 including the channel structure 126′″ of FIG. 2C, or all pillars 124 including the channel structure 126″″ of FIG. 2D). In other embodiments, one or more of the pillars 124 of a respective block 308 may include one configuration of different microstructure sub-regions (e.g., one of the channel structure 126′ of FIG. 2A, the channel structure 126″ of FIG. 2B, the channel structure 126′″ of FIG. 2C, or the channel structure 126″″ of FIG. 2D) while one or more other of the pillars 124 of the respective block 308 may include a different configuration of different microstructure sub-regions (e.g., a different one of the channel structure 126′ of FIG. 2A, the channel structure 126″ of FIG. 2B, the channel structure 126′″ of FIG. 2C, or the channel structure 126″″ of FIG. 2D).

The pillars 124 may effectuate the formation of strings of memory cells of a memory device (e.g., a memory device including the microelectronic device structure 100 of FIG. 1, the microelectronic device structure 300 of FIG. 3 and FIG. 4, and/or any other microelectronic device structure described or illustrated herein). With reference to FIG. 5A and FIG. 5B, illustrated, in enlarged elevational cross-sectional view, are memory cells 502 (e.g., memory cell 502′ of FIG. 5A and memory cell 502″ of FIG. 5B) that may be provided in the microelectronic device structure 100 of FIG. 1, the microelectronic device structure 300 of FIG. 3, and/or any other microelectronic device structure illustrated to include box 106. Each of the illustrations of FIG. 5A and FIG. 5B may represent a simplified enlarged view of box 106 of FIG. 1, FIG. 3, and/or other figures, discussed below, that include box 106. Reference herein to one “memory cell 502” or multiple “memory cells 502” equally refers to one or multiple of any of the illustrated memory cell 502′ of FIG. 5A and/or the illustrated memory cell 502″ of FIG. 5B.

The memory cells 502 are in the vicinity of at least one of the tiers 114, with at least one of the insulative structures 110 vertically adjacent at least one of the conductive structures 112. In some embodiments, such as that illustrated in FIG. 5A, the conductive material(s) 134 of the conductive structures 112 consist essentially of, or consist of, a single conductive material or a homogenous combination of conductive materials either of which is represented by a conductive material 504 illustrated in FIG. 5A. The conductive material 504 may be directly adjacent the insulative material 132 of the insulative structure 110, e.g., without a distinguishable conductive liner.

In other embodiments, such as that illustrated in FIG. 5B, the conductive material(s) 134 of some or all of the conductive structures 112 may include a conductive metal 506 surrounded at least in part by a conductive liner material 508. The conductive liner material 508 may be directly adjacent upper and lower surfaces of neighboring insulative structures 110, respectively. The conductive metal 506 may be directly vertically between portions of the conductive liner material 508.

Memory cells 502″ having the structure of FIG. 5B may be formed by a so-called “replacement gate” process, discussed further below. The conductive liner material 508 may comprise, for example, a seed material that enables formation of the conductive metal 506 during the replacement-gate process. The conductive liner material 508 may be formed of and include, for example, a metal (e.g., titanium, tantalum), a metal nitride (e.g., tungsten nitride, titanium nitride, tantalum nitride), or another material. In some embodiments, the conductive liner material 508 comprises titanium nitride, and the conductive metal 506 comprises tungsten.

With continued reference to FIG. 5A and FIG. 5B, adjacent the tiers 114 are materials of one of the pillars 124 (e.g., FIG. 1) (partially illustrated, in FIG. 5A and FIG. 5B, as a pillar portion 510, which may be about half of the horizontal width, e.g., the diameter, of the pillar 124 of FIG. 1 and other figures). As illustrated in the pillar portion 510, each of the pillars 124 includes the channel material 144 (of the channel structure 126 (FIG. 1)) and the cell materials (e.g., the tunnel dielectric material 138, the memory material 140, and the dielectric blocking material 142) that may each horizontally surround the insulative material 136 at the core (e.g., the axial center) of the pillar 124 (FIG. 1).

In some embodiments of memory cells, such as with the memory cell 502′ of FIG. 5A and the memory cell 502″ of FIG. 5B, the channel material 144 may be horizontally interposed between the insulative material 136 and the tunnel dielectric material 138. The outer sub-region 146 of the channel material 144 may be directly adjacent the tunnel dielectric material 138. The inner sub-region 148 of the channel material 144 may be directly adjacent the insulative material 136. The tunnel dielectric material 138 may be horizontally interposed between the channel material 144 and the memory material 140; and the memory material 140 may be horizontally interposed between the tunnel dielectric material 138 and the dielectric blocking material 142. In some such embodiments, the dielectric blocking material 142 is horizontally interposed between the memory material 140 and a dielectric barrier material (not illustrated), and the dielectric barrier material may be directly adjacent the conductive structure 112 and the insulative structure 110 of the tier 114. In other such embodiments, the dielectric blocking material 142 is directly horizontally interposed between the memory material 140 and the tier 114.

To effectuate the memory cell 502 (e.g., the memory cell 502′ of FIG. 5A, the memory cell 502″ of FIG. 5B), one of the conductive structures 112 horizontally surrounds (e.g., encircles) the materials of the pillar 124 (e.g., FIG. 4). In embodiments corresponding to the memory cell 502′ of FIG. 5A, the conductive material 504 horizontally surrounds the materials of the pillar 124 (e.g., FIG. 4); whereas, in embodiments corresponding to the memory cell 502″ of FIG. 5B, both the conductive metal 506 and the conductive liner material 508 horizontally surround the materials of the pillar 124 (e.g., FIG. 4).

Accordingly, each of the pillars 124 (e.g., FIG. 3) may provide a string of memory cells 502 extending vertically, or at least partially vertically, through the stack structure 108 (FIG. 3), from the source region 120 (FIG. 3) to a drain region above the stack structure 108. As described above, the channel material 144 (forming the channel structure 126 (FIG. 1)) is formed in multiple sub-regions of different microstructures so as to facilitate, in a thin total channel material 144 wall, sufficient electron mobility and string current through the larger-grain inner sub-region 148 while the smaller or non-grains of the outer sub-region 146 inhibit chemical species damage at the interface between the channel material 144 and the tunnel dielectric material 138 that may otherwise lead to loss of data retention in the memory cells 502 (e.g., in the memory material 140 of the memory cell 502).

Accordingly, disclosed is a microelectronic device comprising a stack structure and at least one pillar extending through the stack structure. The stack structure comprises a vertically alternating sequence of insulative structures and conductive structures arranged in tiers. The at least one pillar comprises at least one insulative material and a channel structure horizontally surrounding the at least one insulative material. The channel structure comprises sub-regions of semiconductor material. At least one of the sub-regions exhibits a different microstructure than at least one other of the sub-regions.

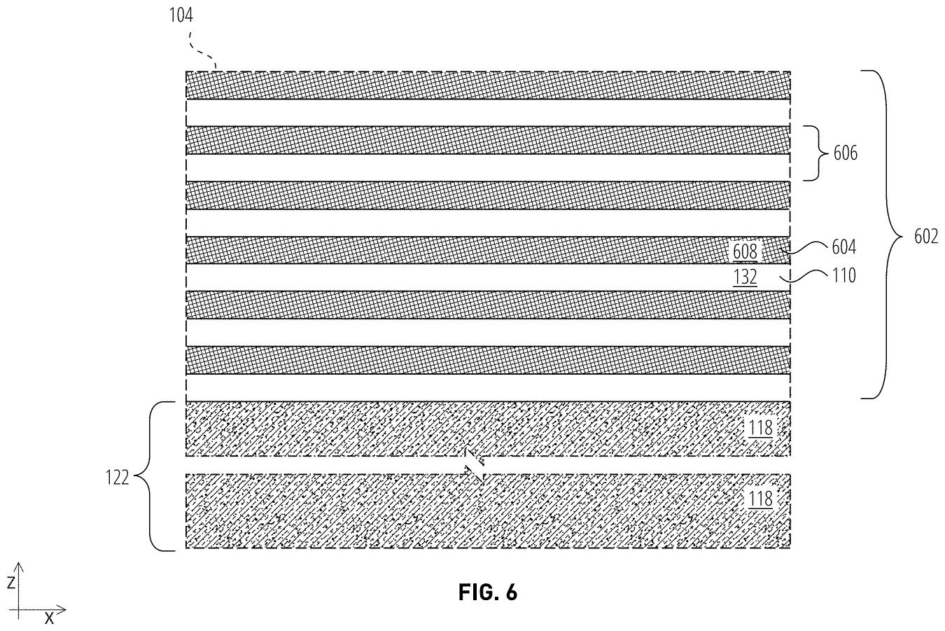

With reference to FIG. 6 through FIG. 21, illustrated are various stages for forming a microelectronic device, such as one including the microelectronic device structure 100 of FIG. 1 and/or the microelectronic device structure 300 of FIG. 3.

With reference to FIG. 6, a stack structure 602 is formed on the base structure 122. The stack structure 602 is formed to include a vertically alternating sequence of the insulative structures 110 and sacrificial structures 604 arranged in tiers 606. The sacrificial structures 604 may be formed at levels of the stack structure 602 that will eventually be replaced with or otherwise converted into the conductive structures 112 (FIG. 1).

The sacrificial material 608 of the sacrificial structures 604 may be selected or otherwise formulated to be selectively removable (e.g., selectively etchable) relative to the insulative material 132 of the insulative structures 110. In some embodiments, the insulative material 132 comprises silicon dioxide and the sacrificial material 608 comprises silicon nitride.

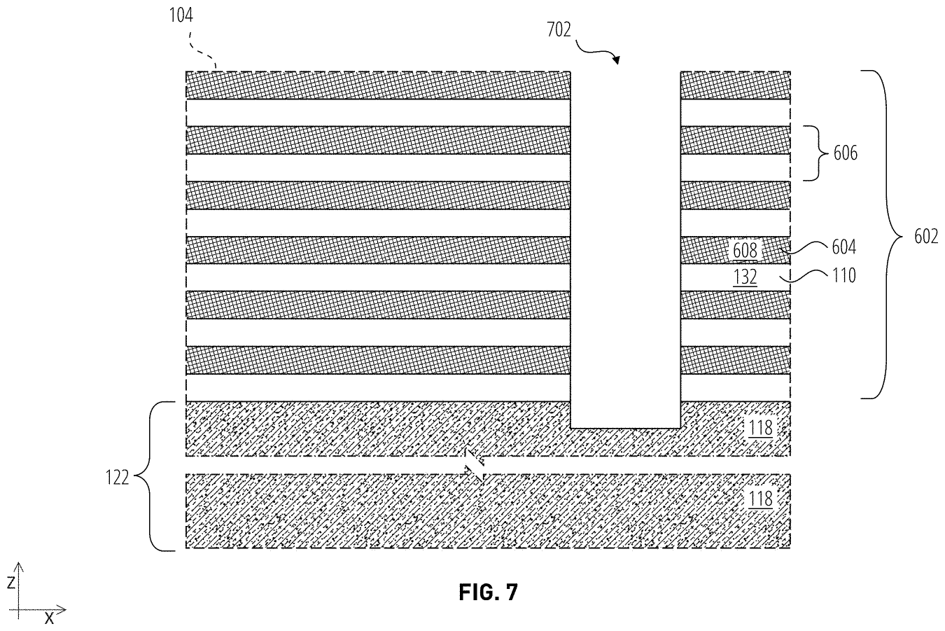

To form the stack structure 602, formation (e.g., deposition) of the insulative materials 132 of the insulative structures 110 may be alternated with formation (e.g., deposition) of the sacrificial material 608 of the sacrificial structures 604. In some embodiments, the stack structure 602 may be formed, at this stage, to include as many tiers 606 with sacrificial structures 604 as there will be tiers 114 (FIG. 1) of conductive structures 112 (FIG. 1) in all deck(s) (e.g., the lower deck 302, the upper deck 304 (FIG. 3)) of the microelectronic device structure being fabricated (e.g., the microelectronic device structure 300 of FIG. 3). In other embodiments, only the tiers 114 of the lower deck 302 are formed at this stage, and the subsequent stages illustrated in FIG. 7 through FIG. 21 may be carried out only in or for the lower deck 302, prior to fabricating the upper deck 304.

With reference to FIG. 7, pillar openings 702 may be formed (e.g., etched) through the stack structure 602 and to or into the base structure 122. The arrangement of the pillar openings 702 may correspond to the arrangement of the pillars 124 (see FIG. 4) to be formed in the pillar array portion 310 (FIG. 3 and FIG. 4).

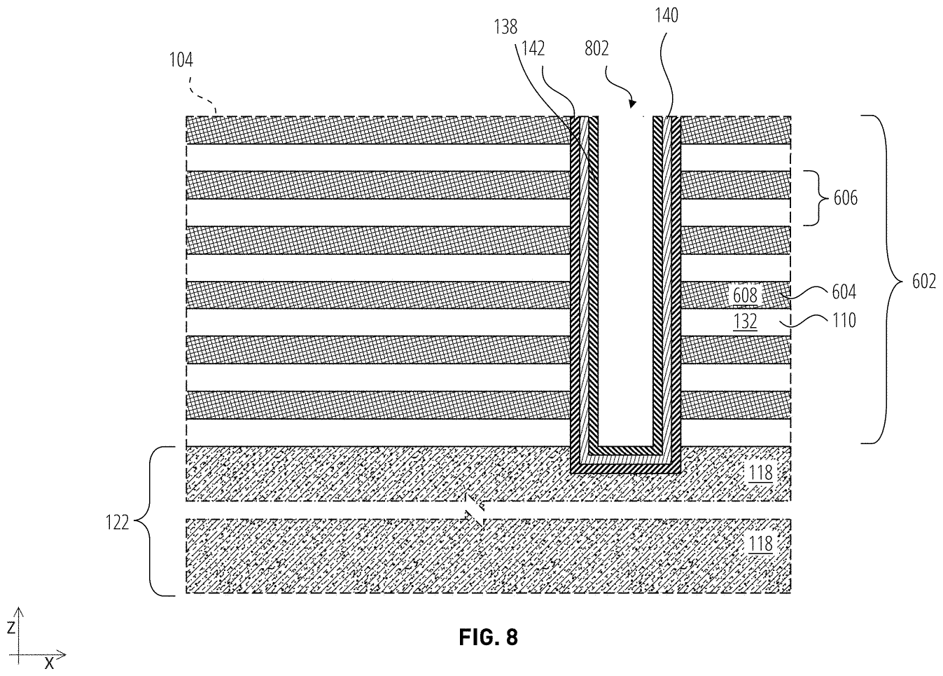

Within each of the pillar openings 702, the cell materials of the pillars 124 (FIG. 1) may be formed. Accordingly, as illustrated in FIG. 8, the dielectric barrier material, if any, the dielectric blocking material 142, the memory material 140, and the tunnel dielectric material 138 may be formed (e.g., conformally deposited) in sequence, covering the sidewall and the base of the pillar openings 702 (FIG. 7), leaving openings 802 defined by the tunnel dielectric material 138.

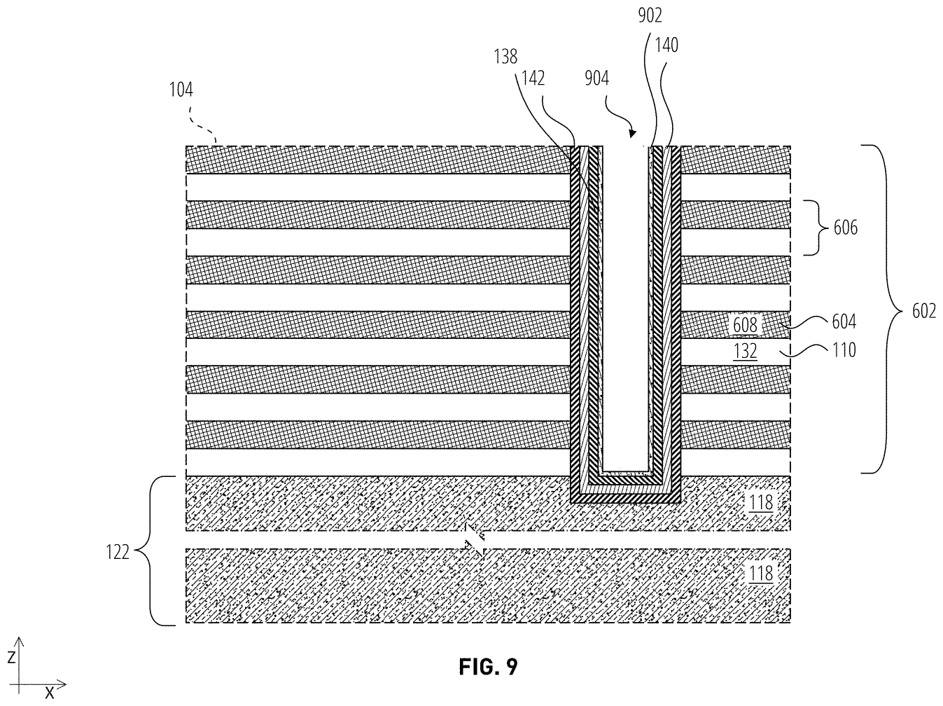

To expose the base structure 122 at the base of the pillar 124 (FIG. 1) so that the channel material 144 (FIG. 1) may be formed in contact with the doped material 118 (FIG. 1) of the source region 120, an opening may be formed through the cell materials at the base of the opening 802. In some embodiments, this may include forming, in the opening 802, a liner material 902—as illustrated in FIG. 9—to protect the sidewall portions of the cell materials while forming the base opening through the cell materials. The liner material 902 may be formed (e.g., conformally formed, deposited) as a relatively thin (e.g., less than about 5 nm in thickness) on the tunnel dielectric material 138, leaving an opening 904 defined by the liner material 902.

The liner material 902 may be formed of and include, for example, a semiconductor material such as polysilicon. In some embodiments, the liner material 902 may be a sacrificial material to be substantially removed during subsequent processing. In other embodiments, the liner material 902 may not be a sacrificial material, as described further below.

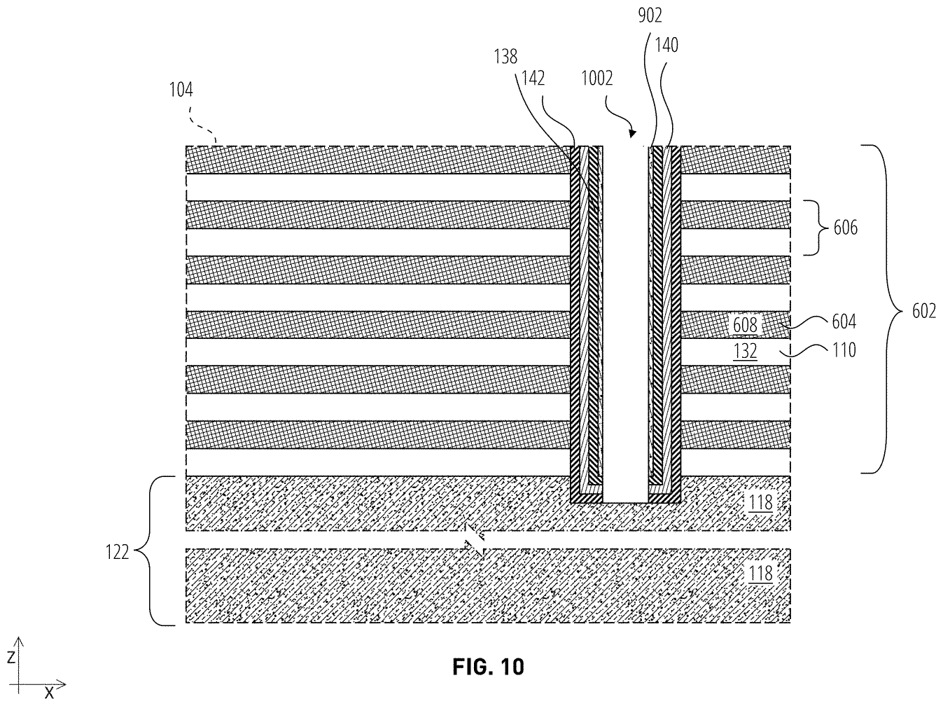

With reference to FIG. 10, a base portion of the liner material 902 may be selectively removed (e.g., directionally etched, such as directionally dry etched) to leave a sidewall (e.g., cylinder) of the liner material 902 covering the sidewall of cell materials (e.g., the tunnel dielectric material 138, the memory material 140, the dielectric blocking material 142). Portions of the cell materials exposed after removing the base portion of the liner material 902 may then be also etched vertically downward to expose a portion of the base structure 122 (e.g., the doped material 118 (FIG. 1) of the source region 120 (FIG. 1)) at the base of each opening 1002.

During either or both of the selective removal of a base portion of the liner material 902 and/or the removal of base portions of the cell materials, the liner material 902 may be thinned. Accordingly, the liner material 902 remaining in the stage of FIG. 10 may be thinner than the liner material 902 initially formed as illustrated in FIG. 9. In other embodiments, the thickness of the liner material 902 in the stage of FIG. 10 may be about the same as the thickness of the liner material 902 in the stage of FIG. 9.

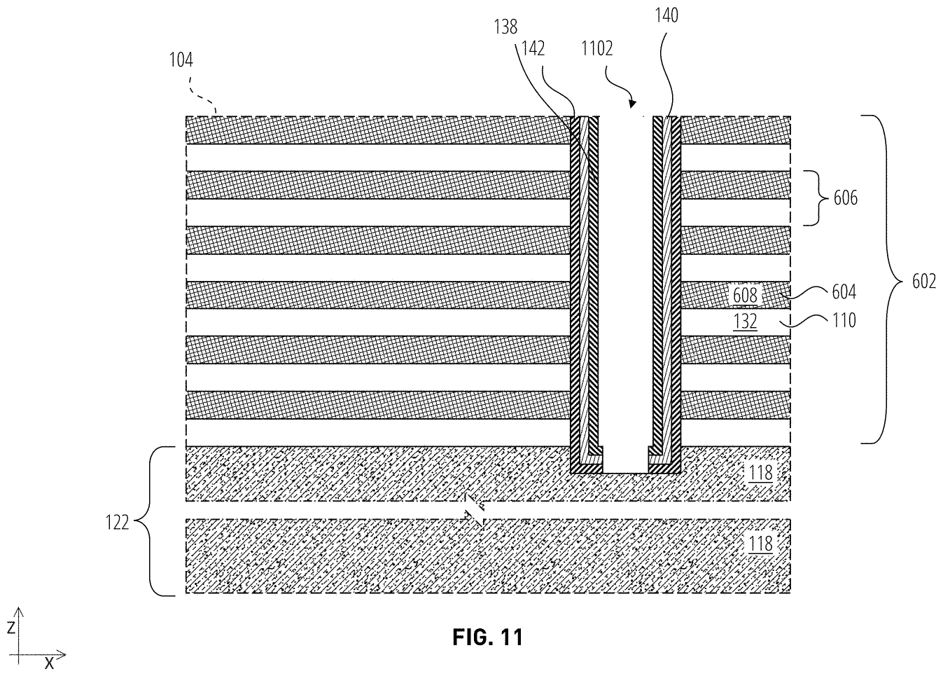

After forming the opening 1002 exposing a portion of the base structure 122, the remaining portions of the liner material 902 may be removed, in embodiments in which the liner material 902 is a sacrificial material. Accordingly, as illustrated in FIG. 11, the tunnel dielectric material 138 may define sidewalls of an opening 1102. The portion of the base structure 122 is exposed at the base of the opening 1102.

In some embodiments, the cell materials may somewhat horizontally extend adjacent the base of the opening 1102, where previously vertically covered by the liner material 902 (FIG. 10).

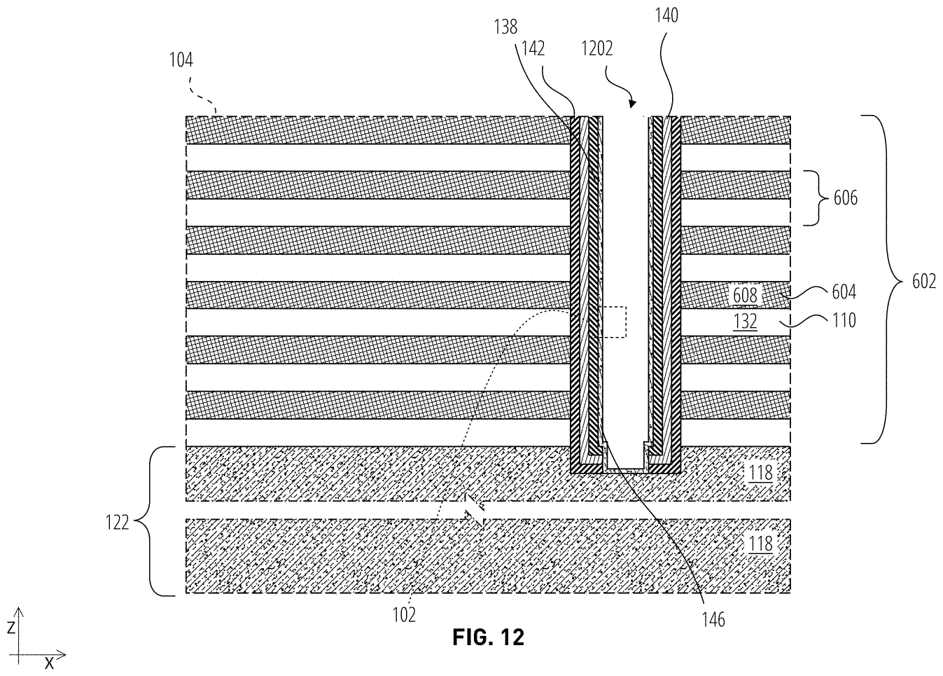

The channel structure 126 (FIG. 1) is then formed—in multiple sub-regions—in the opening 1102, with at least a part of the channel material 144 (FIG. 1) in direct physical contact with the exposed portion of the base structure 122 (e.g., with the doped material 118 of the source region 120). First, the outer sub-region 146 is formed (e.g., conformally deposited) on the cell materials (e.g., on or directly on the tunnel dielectric material 138) and the exposed portion of the base structure 122, as illustrated in FIG. 12. An opening 1202 is defined by the outer sub-region 146.

The conditions of forming (e.g., depositing) the material of the outer sub-region 146 may be tailored to promote the formation of the small grains 204 (FIG. 2A, FIG. 2D) or to inhibit the formation of grains (e.g., as in the amorphous material 206 of FIG. 2B or FIG. 2C) in the outer sub-region 146, as illustrated and discussed below with regard to FIG. 13A to FIG. 13D.

With reference to FIG. 13A—in a method to form the outer sub-region 146 with the small grains 204 in accordance with the channel structure 126′ of FIG. 2A—the material of the outer sub-region 146 may be formed to substantially only its relatively small, final intended thickness (e.g., less than about 50% of the intended total thickness of the channel structure 126′ (FIG. 2A), such as less than about 5 nm). Forming such a thin-as-deposited structure of the material of the outer sub-region 146 may promote forming the small grains 204 (FIG. 2A, FIG. 2D). In some such embodiments, the outer sub-region 146 may consist essentially of or consist of small grains 204 of polysilicon.

With reference to FIG. 13B—in a method to form the outer sub-region 146 as the amorphous material 206 in accordance with the channel structure 126″ previously described with reference to FIG. 2B—the material of the outer sub-region 146 may be formed by formulating the precursor(s) of the deposition (e.g., CVD) process to be hydrogen rich. For example, one or more precursors such as disilane (Si₂H₆) and/or trisilane (e.g., Si₃H₈, H₈Si₃, H₂Si(SiH₃)₂) may be used during the deposition of the outer sub-region 146. In some such embodiments, the outer sub-region 146 is deposited only thinly to substantially its final desired thickness (e.g., less than about 50% of the intended total thickness of the channel structure 126″ (FIG. 2B), such as less than about 5 nm).

Accordingly, the amorphous material 206 may include a semiconductor material (e.g., silicon) comprising a trace chemical species (e.g., hydrogen (H) atoms). The presence of the hydrogen may inhibit crystallization of the semiconductor material (e.g., the silicon) of the outer sub-region 146, even if or when the material of the outer sub-region 146 is exposed to high temperatures (e.g., annealed). Accordingly, the formed material of the outer sub-region 146 may remain as the amorphous material 206 up to higher temperatures than if formed from precursors not rich in hydrogen (e.g., monosilane precursors).

With reference to FIG. 13C—in a method to form the outer sub-region 146 as the amorphous material 206 with dopant 208 in accordance with the channel structure 126′″ previously described with reference to FIG. 2C—the material of the outer sub-region 146 may be formed as described above with regard to either or both of FIG. 13A and FIG. 13B and also in the presence of the dopant 208 (e.g., carbon atoms) to form the amorphous material 206 with a dopant 208 concentration of at least about 1×10¹⁵ atoms of the dopant 208 per cm³ of the amorphous material 206. For example, a carbon-including component (e.g., gas or gaseous mixture) may be introduced while the outer sub-region 146 is being deposited so that carbon dopant 208 is incorporated into the amorphous material 206. Such a carbon-including component may be a hydrocarbon (e.g., one or more species with the formal CₓH_{y}, such as one or more of CH₃ and/or C₂H₄). The presence of the dopant 208 in the outer sub-region 146 may inhibit crystallization of the semiconductor material (e.g., the silicon) of the outer sub-region 146, resulting in the amorphous material 206.

By this method, the outer sub-region 146 may be formed of and include amorphous semiconductor material (e.g., silicon) also comprising the dopant 208 (e.g., carbon). In some embodiments, the outer sub-region 146 also includes trace amounts of hydrogen, in accordance with the descriptions previously provided with reference to FIG. 13B. Methods of the disclosure including formation of the outer sub-region 146 as the amorphous material 206—whether with or without the dopant 208—may utilize the hydrogen-rich precursors described above. Therefore, in some embodiments, the amorphous material 206 includes trace amounts of hydrogen.

In some embodiments, the dopant 208 is substantially evenly distributed throughout the amorphous material 206. In other embodiments, the dopant 208 is concentrated at or near an interior or exterior surface of the amorphous material 206 in the outer sub-region 146.

With reference to FIG. 13D—in a method to form the outer sub-region 146 as the small grains 204 including the dopant 208 in accordance with the channel structure 126″″ previously described with reference to FIG. 2D—the material of the outer sub-region 146 may be formed as described above with regard to FIG. 13A while also providing the component comprising the dopant 208 (e.g., while introducing the carbon-including component). The presence of the dopant 208 may discourage, but not wholly prevent, crystallization of the semiconductor material of the outer sub-region 146, such that the small grains 204 form and include the dopant 208.

By this method, the outer sub-region 146 may be formed of and include, e.g., polysilicon silicon also comprising the dopant 208 (e.g., carbon). In some such embodiments, the dopant 208 is substantially evenly distributed through the small grains 204. In other embodiments, the dopant 208 is concentrated at the surface(s) of the small grains 204.

Optionally, after thinly forming (e.g., conformally depositing) the material of the outer sub-region 146, in accordance with any of FIG. 13A through FIG. 13D, a high-temperature process (e.g., a rapid thermal anneal) may be performed to facilitate reducing the size of (e.g., for the outer sub-region 146 of FIG. 13A and/or FIG. 13D), or to eliminate (e.g., for the outer sub-region 146 illustrated in FIG. 13B and/or FIG. 13C) grains of material that may have originally formed during the deposition. With regard to the outer sub-region 146 illustrated in FIG. 13A and FIG. 13D, the high-temperature exposure may cause the outer sub-region 146 to have—along its interior surface—primarily nanograins as the small grains 204 (e.g., the small grains 204 with an average maximum length of less than about 1 μm). With regard to the outer sub-region 146 of FIG. 13B and FIG. 13C, the high-temperature exposure may not substantially crystalize the amorphous material 206 (e.g., due to the presence of the hydrogen trace species of FIG. 13B and/or due to the presence of the dopant 208 of FIG. 13C).

After thinly depositing the semiconductor material of the outer sub-region 146 and, optionally, conducting the high-temperature process, a cleaning process (e.g., exposure of an interior surface of the outer sub-region 146 to hydrofluoric acid (HF)) may be conducted to remove native oxide.

As formed, the increased grain boundary density and grain boundary complexity of the outer sub-region 146 formed of small grains 204 (FIG. 13A and FIG. 13D) and/or the amorphous nature of the amorphous material 206 of the outer sub-region 146 (FIG. 13B and FIG. 13C) may inhibit chemical species (e.g., oxygen) from traversing the outer sub-region 146 to the interface with the tunnel dielectric material 138.

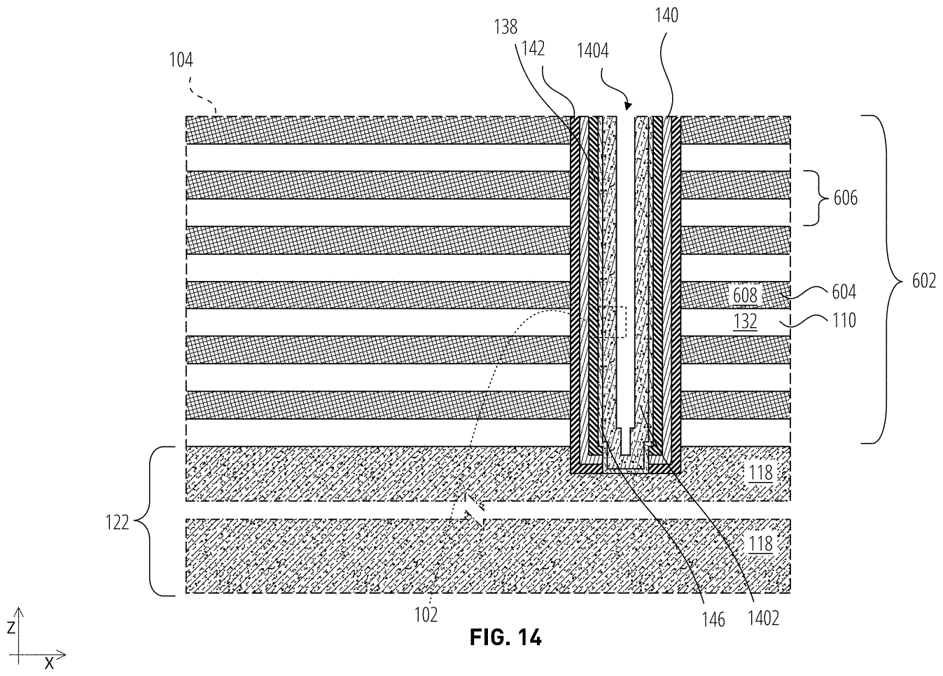

With reference to FIG. 14, the remaining channel material 144 (FIG. 1) of the channel structure 126 (FIG. 1) may then be formed (e.g., conformally deposited) on the outer sub-region 146. The conditions for forming the remaining channel material 144 (FIG. 1) may be controlled to facilitate formation of the large grains 202 (FIG. 2A through FIG. 2D) in the semiconductor material (e.g., polysilicon) of the inner sub-region 148 (FIG. 1). In some embodiments, the semiconductor material may be deposited to an initial thickness that is greater than (e.g., at least 10% greater than, at least 20% greater than) its intended final thickness, e.g., as a thickly-deposited channel material 1402 illustrated in FIG. 14. For example, in an embodiment in which the final inner sub-region 148 is intended to have a thickness of at least about 5 nm, the thickly-deposited channel material 1402 may be deposited to an initial thickness of at least about 6 nm. An opening 1404 may remain, lined by the thickly-deposited channel material 1402.

As described above, forming a semiconductor material to an initially greater thickness may facilitate the formation of the material with large grains 202 (FIG. 2A through FIG. 2D). With reference to FIG. 15A through FIG. 15D, other conditions of the formation of the thickly-deposited channel material 1402 may be controlled to facilitate the formation of the large grains 202 in the material.

In some embodiments, the formation of the thickly-deposited channel material 1402 is a continuation of the formation of the outer sub-region 146, but with modified deposition conditions. Therefore, the same material-formation apparatus (e.g., deposition chamber) may be used for forming the outer sub-region 146 as for forming the thickly-deposited channel material 1402, e.g., without purging the chamber and/or without removing deposited structures from the chamber, between forming the outer sub-region 146 and forming the thickly-deposited channel material 1402. Accordingly, the sub-regions of the channel structure 126 may be formed in situ.

In some embodiments, the sub-regions of the channel structure 126 may be formed ex situ, e.g., using the same or different material-formation apparatuses (e.g., deposition chamber(s)). For example, between forming the outer sub-region 146 and forming the thickly-deposited channel material 1402 in a single deposition chamber, the chamber may be purged (or a vacuum condition otherwise broken). As another example, the outer sub-region 146 may be formed in one deposition chamber and then the intermediate structure(s) may be transported to another deposition chamber for formation of the thickly-deposited channel material 1402.

In some embodiments, the conditions for forming the small grains 204 or the amorphous material 206 are continued until the desired thickness of the outer sub-region 146 is reached, then the conditions are changed to facilitate formation of the large grains 202. For example, if the outer sub-region 146 was formed using hydrogen-rich precursors, the flow of the hydrogen-rich precursors may be halted—once the outer sub-region 146 deposition reaches its desired thickness—and changed to introduce a non-hydrogen-rich precursor (e.g., monosilane) while the thickly-deposited channel material 1402 is formed on the outer sub-region 146. The non-hydrogen-rich precursor (e.g., monosilane) may facilitate formation of the thickly-deposited channel material 1402 with the large grains 202. As another example, if the outer sub-region 146 was formed with the dopant 208, the flow of the dopant 208 source may be ceased after the outer sub-region 146 deposition is completed so that the remaining deposition of semiconductor material (e.g., polysilicon) is substantially free of the dopant 208. The absence of the hydrogen trace species and/or the dopant 208—which may otherwise have inhibited crystallization—may promote formation of the large grains 202.

The resulting thickly-deposited channel material 1402 may be substantially free of the dopant 208 and/or may be substantially free of the hydrogen trace species. Alternatively, the thickly-deposited channel material 1402 may have a significantly lower concentration of the dopant 208 and/or a significantly lower concentration of the hydrogen trace species, compared to concentration(s) in the outer sub-region 146.

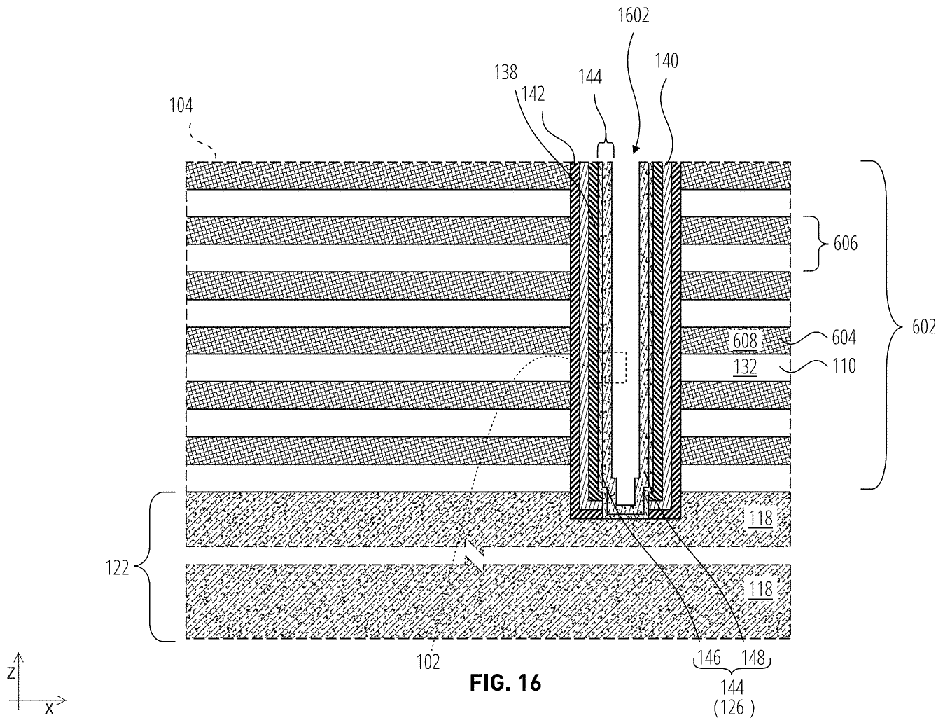

After forming the thickly-deposited channel material 1402, the thickly-deposited channel material 1402 may be thinned to the final desired thickness of the inner sub-region 148, as illustrated in FIG. 16 and FIG. 17A through FIG. 17D, to complete the formation of the channel material 144 of the channel structure 126. An opening 1602 remains, defined by the inner sub-region 148.

To thin the thickly-deposited channel material 1402 (FIG. 14), an oxidation process may be performed to remove portions along the opening 1404 (FIG. 14). The oxidation process may include introducing an oxidizing etch chemistry such as, e.g., an ammonium peroxide mixture (e.g., H₂O₂ and NH₄OH) to remove material along the surface of the thickly-deposited channel material 1402. In other embodiments, the oxidation process may include an in situ steam generation (ISSG) process, a thermal oxidation process, a plasma oxidation process, or other oxidation technique(s) in combination with introducing hydrofluoric acid (HF). Such oxidation processes and chemistries are generally conducive for controlled etching of polycrystalline semiconductor material, such as the polysilicon of the large grains 202.

In some embodiments, the thinning process may be free of use of non-oxidizing chemistries—such as mixtures of tetramethylammonium hydroxide (TMAH) and ammonium hydroxide (NH₄OH)—which tend to remove material in a manner dependent on grain crystal orientation. That is, such non-oxidizing chemistries may exhibit high selectivity for one crystal plane over another and so may not be conducive for substantially evenly thinning the thickly-deposited channel material 1402 (FIG. 14) to form the inner sub-region 148. Accordingly, in some embodiments, the methods of formation may be free of use of non-oxidizing material-removal processes while the channel material 144 is exposed.

Though the aforementioned oxidizing etch chemistries may facilitate controlled etching of the thickly-deposited channel material 1402 (FIG. 14) (e.g., polycrystalline semiconductor material), exposing the large grains 202 of material to these oxidizing etch chemistries may result in oxygen (or other chemical species) being introduced into grain boundaries of the resulting inner sub-region 148. Native oxide formation may also lead to oxygen at the grain boundaries. Moreover, due to the relative simplicity of the grain boundary network in the inner sub-region 148 (e.g., see FIG. 17A through FIG. 17D), the oxygen or other chemical species may not be substantially inhibited from traveling along the grain boundaries across the inner sub-region 148. However, by forming the channel structure 126 (e.g., the channel structure 126′ illustrated in FIG. 17A, the channel structure 126″ illustrated in FIG. 17B, the channel structure 126′″ illustrated in FIG. 17C, the channel structure 126″″ illustrated in FIG. 17D) with the multiple sub-regions, in accordance with embodiments of the disclosure, the microstructural difference along the interface between the inner sub-region 148 (with its large grains 202) and the outer sub-region 146 (with its small grains 204 or amorphous material 206) may inhibit oxygen (or other chemical species) from traversing through the outer sub-region 146 to the exterior surface of the channel material 144 that interfaces with the tunnel dielectric material 138. For example, oxygen species traversing the grain boundary of the large grains 202 in the inner sub-region 148 may essentially hit a “dead end” at the interface with the small grains 204 or amorphous material 206 of the outer sub-region 146. By inhibiting chemical species, such as oxygen, from traveling to the exterior surface of the channel material 144, oxidation or other material damage—at the exterior surface and interface with neighboring material(s) (e.g., the tunnel dielectric material 138)—may be avoided or lessened. For example, surface roughening may be avoided, such that the channel structure 126 may have a relatively smoother outer surface than if formed with the large grains 202 along its exterior surface. With a relatively smoother exterior surface, localized electrical fields may not form, so data leakage from the memory material 140 (FIG. 1) may be avoided, improving data retention.

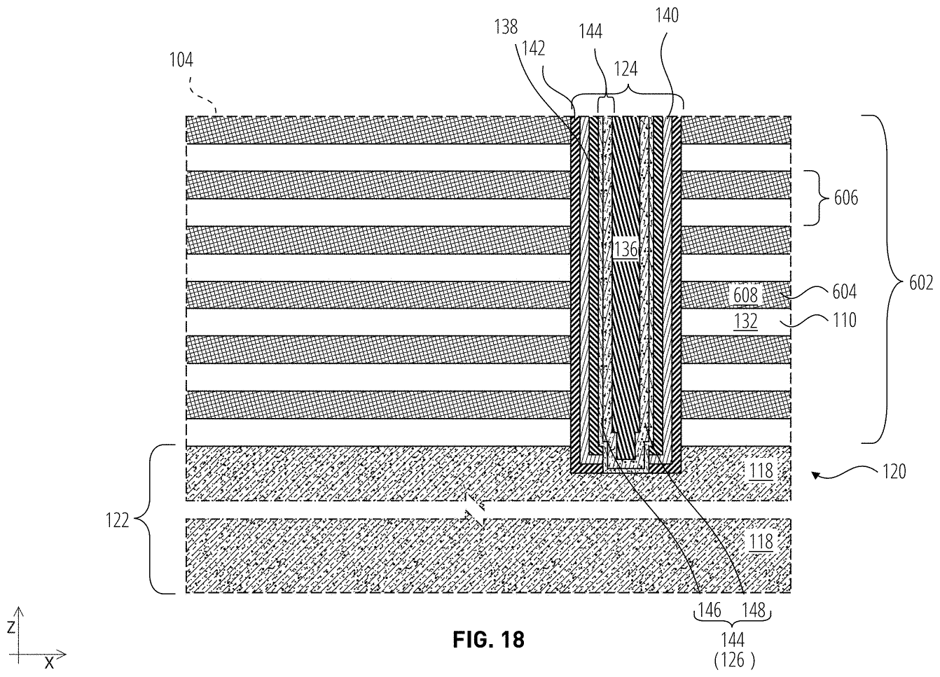

With reference to FIG. 18, the insulative material 136 may be formed (e.g., deposited) on (e.g., directly on) the large-grain inner sub-region 148 (FIG. 17A to FIG. 17D) to fill or substantially fill the remaining space (e.g., the opening 1602) defined by the channel material 144 and complete the formation of the pillar 124. In embodiments in which the insulative material 136 is air, additional material formation is not needed to complete the formation of the pillar 124 after completing the formation of the channel material 144 of the channel structure 126.

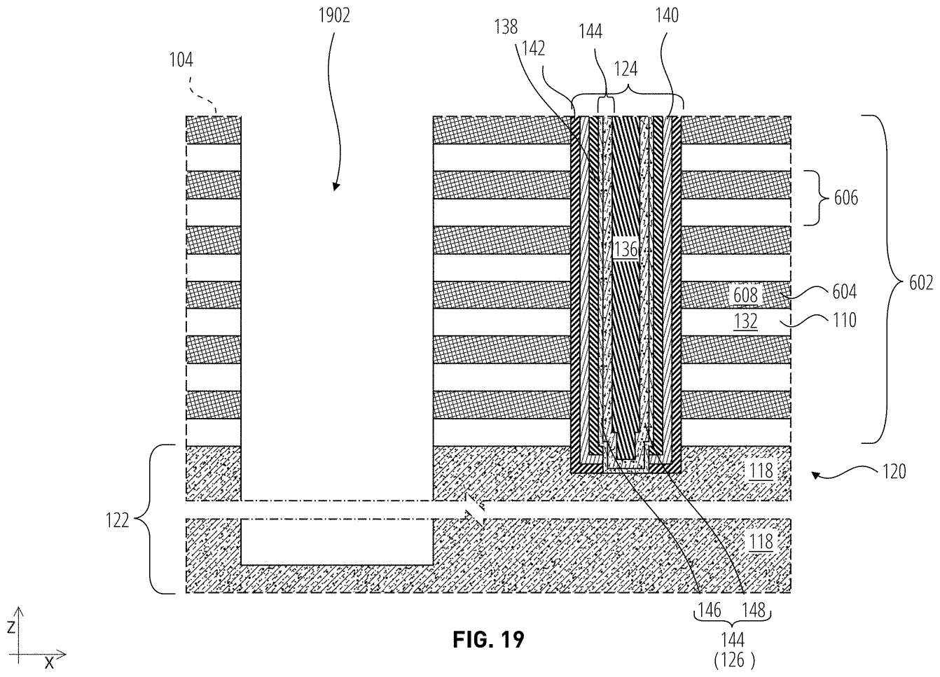

With reference to FIG. 19, a slit 1902 is formed (e.g., etched) for each slit structure 116 (FIG. 1) to be formed in the microelectronic device structure (e.g., the microelectronic device structure 100 of FIG. 1, the microelectronic device structure 300 of FIG. 3 and/or FIG. 4). Each slit 1902 is formed to extend through the stack structure 602 and to or into the base structure 122 (e.g., the doped material 118 of the source region 120). In the slit 1902, ends of the sacrificial structures 604 and the insulative structures 110 of the stack structure 602 are exposed.

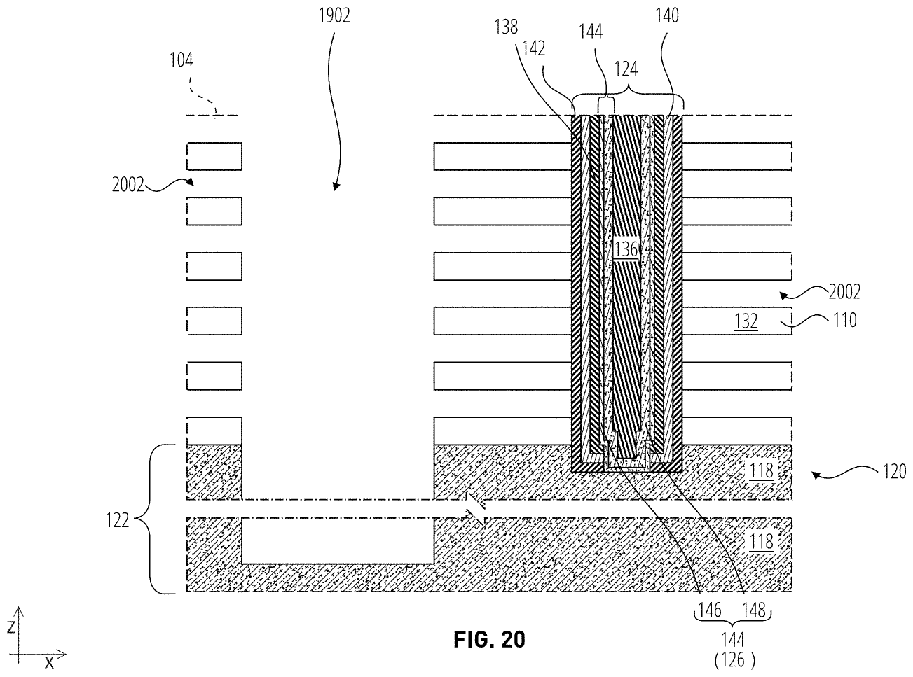

A “replacement gate” process may be performed, via the slit 1902, to at least partially (e.g., substantially) exhume the sacrificial material 608—and therefore the sacrificial structures 604—leaving voids 2002 (e.g., void spaces, gaps) between the insulative structures 110, as illustrated in FIG. 20.

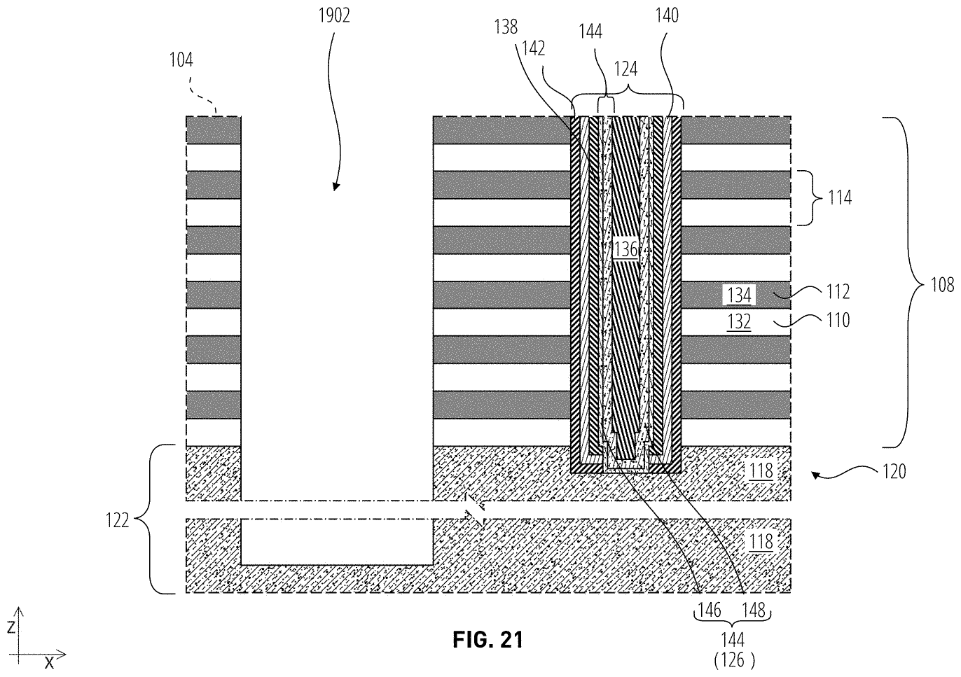

In the voids 2002, the conductive material(s) 134 are formed, as illustrated in FIG. 21 to form the conductive structures 112 of the tiers 114 of the stack structure 108. For example, in accordance with the memory cells 502′ previously described with reference to FIG. 5A, the conductive material 504 (FIG. 5A) may be formed in the voids 2002, directly on the insulative material 132. As another example, in accordance with the memory cells 502″ previously described with reference to FIG. 5B, the conductive liner material 508 (FIG. 5B) may be formed directly on the insulative material 132, and then the conductive metal 506 (FIG. 5B) may be formed on the conductive liner material 508 to form the conductive material(s) 134.

In the slit 1902, the insulative liner 128 (FIG. 1) may be formed (e.g., deposited) on sidewalls of the tiers 114 of the stack structure 108. The nonconductive fill material 130 (FIG. 1) may be formed (e.g., deposited) to fill or substantially fill a remaining volume between the insulative liner 128 to complete the slit structure 116 (FIG. 1) (e.g., for each of the slit structures 116 of the microelectronic device structure 300 of FIG. 3 and FIG. 4).

Accordingly, disclosed is a method of forming a microelectronic device. The method comprises forming a tiered stack structure on a base structure. The tiered stack structure comprises a vertically alternating sequence of insulative structures and other structures arranged in tiers. A pillar opening is formed through the tiered stack structure and at least to the base structure. Cell materials are formed in the pillar opening. On the cell materials, an outer sub-region of a channel structure is formed. The outer sub-region comprises at least one of amorphous silicon and small grains of polysilicon having an average grain size of less than about 0.01 μm (e.g., less than about 0.005 μm). On the outer sub-region, an inner sub-region of the channel structure is formed. The inner sub-region comprises large grains of polysilicon having an average grain size of greater than about 0.01 μm. At least one insulative material is formed on the inner sub-region of the channel structure to form a core of a pillar.

By the method(s) described with reference to FIG. 6 through FIG. 21 and then FIG. 1—wherein the outer sub-region 146 is formed after removing the liner material 902 used to provide an opening through the cell materials at the base of the pillar 124—the resulting channel structure 126 (e.g., the channel structure 126′ illustrated in FIG. 17A, the channel structure 126″ illustrated in FIG. 17B, the channel structure 126′″ illustrated in FIG. 17C, the channel structure 126″″ illustrated in FIG. 17D) includes the outer sub-region 146 of the channel material 144 both horizontally surrounding and underlying the inner sub-region 148 of the channel material 144. The outer sub-region 146 is also in directly physical contact with the base structure 122 at the base of the pillar 124 (FIG. 1).

In other embodiments, such as that illustrated in FIG. 22 through FIG. 25, the liner material 902 (FIG. 9) is not be wholly removed during the fabrication process, but may be employed for the outer sub-region 146 of the channel material 144 for the channel structure 126. For example, after the processing stages previously described with reference to FIG. 6 through FIG. 10, the liner material 902 may be substantially maintained (e.g., may not be removed), as illustrated in FIG. 22. The liner material 902 may have been formed in a manner consistent with the illustrations of any one or more of FIG. 13A through FIG. 13D, before the base portion of the liner material 902 is removed and the base portion of the cell materials removed to expose the portion of the base structure 122, as illustrated in FIG. 22 and discussed above with regard to FIG. 10. Accordingly, the liner material 902 may provide the outer sub-region 146, but without the outer sub-region 146 extending across or in direct contact with the base structure 122 at the base of the pillar structure in fabrication.

Next, as illustrated in FIG. 23, the thickly-deposited channel material 1402 may be formed, in substantially the same manner described above with regard to FIG. 14 and FIG. 15A through FIG. 15D. However, given the opening in the base of the liner material 902 (e.g., the outer sub-region 146), the thickly-deposited channel material 1402 may be formed in direct contact with the portion of the base structure 122 at the base of the structure.

The thickly-deposited channel material 1402 may then be thinned in substantially the same manner as described above with regard to FIG. 16 and FIG. 17A through FIG. 17D, forming the channel structure 126 as illustrated in FIG. 24. Notably, depending on the conditions for forming the liner material 902 (e.g., the outer sub-region 146), the channel structure 126 may be in accordance with the channel structure 126′ illustrated in FIG. 2A, the channel structure 126″ illustrated in FIG. 2B, the channel structure 126′″ illustrated in FIG. 2C, and/or the channel structure 126″″ illustrated in FIG. 2D. Accordingly, the resulting channel structure 126 includes the inner sub-region 148 of the channel material 144 in direct physical contact with the base structure 122 (e.g., the doped material 118 (FIG. 1) of the source region 120 (FIG. 1)) and with the outer sub-region 146 horizontally surrounding (but not underlying) the inner sub-region 148.

After forming the channel structure 126, as illustrated in FIG. 24, the remaining stages of the fabrication method may continue as described above with regard to FIG. 18 through FIG. 21 and FIG. 1, to form a microelectronic device structure 2500 illustrated in FIG. 25. Notably, at least in elevations of the stack structure 108 including the conductive structures 112, the materials and structures of the channel structure 126 (e.g., the outer sub-region 146, inner sub-region 148, and any intervening sub-regions of the channel material 144) may be substantially the same as described above with regard to the microelectronic device structure 100 illustrated in FIG. 1.

The microelectronic device structure 2500, illustrated in the box 104 of FIG. 25, may be included as a portion of a larger microelectronic device structure 2600, illustrated in FIG. 26, such as the microelectronic device structure 100 of FIG. 1 may be included in the microelectronic device structure 300 of FIG. 3, as described above. The top plan schematic illustrated in FIG. 4 may likewise illustrate a top plan schematic of the pillar array portion 310 of the microelectronic device structure 2600 of FIG. 26, wherein the view of the pillar array portion 310 of FIG. 26 may be taken along section line A-A of FIG. 4, and the view of the microelectronic device structure 2500 of FIG. 25 may be taken along section line B-B of FIG. 4.

The method illustrated by the stages of FIG. 6 through FIG. 21 and then FIG. 1 and/or the method illustrated by the stages of FIG. 6 through FIG. 10 and then FIG. 22 through FIG. 25 may be performed for the lower deck 302 of the microelectronic device structure 300 (FIG. 3) before forming the upper deck 304 of the microelectronic device structure 300. For example, after completing the formation of the microelectronic device structure 100 of FIG. 1 and/or the microelectronic device structure 2500 of FIG. 25 to form the lower deck 302 (FIG. 3), as described above, additional tiers 606 (FIG. 6) of sacrificial structures 604 vertically interleaved with insulative structures 110 are formed on the lower deck 302; the portions of the pillars 124 of the upper deck 304 are formed through the additional tiers 114; an upper slit (e.g., like the slit 1902 through the stack structure 602 of FIG. 19) is formed through the additional tiers 606; the replacement gate process is performed to replace the sacrificial structures 604 with conductive structures 112 of the upper deck 304; and the materials of the slit structure 116 are formed in the slit of the upper deck 304 to form the microelectronic device structure 300 of FIG. 3 and FIG. 4 and/or the microelectronic device structure 2600 of FIG. 26 and FIG. 4, including the microelectronic device structure 100 of FIG. 1 and/or the microelectronic device structure 2500 of FIG. 25 in the lower deck 302.

In some embodiments, the tiers 606 and pillars 124 of the lower deck 302 (FIG. 3) and the upper deck 304 are formed in separate processing stages prior to conducting the replacement gate process. For example, before forming the slit 1902 (FIG. 19), the processing stages previously described with reference to FIG. 6 through FIG. 18 may be performed to form the lower deck 302 of the microelectronic device structure 300 illustrated in FIG. 3; or the processing stages previously described with reference to FIG. 6 through FIG. 10 then FIG. 22 through FIG. 24 and then the formation of the tunnel dielectric material 138 may be performed to fabricate the lower deck 302 of the microelectronic device structure 2600 illustrated in FIG. 26. Then, these processing stages may be repeated above the lower deck 302 to form the upper deck 304 of the microelectronic device structure 300 illustrated in FIG. 3 or the microelectronic device structure 2600 illustrated in FIG. 26. Then, with the pillars 124 and stack structures 602 of both the lower deck 302 and the upper deck 304 formed, the slits 1902 (FIG. 19) may be formed through both the upper deck 304 and the lower deck 302, the replacement gate process performed (FIG. 20 and FIG. 21) to replace the sacrificial structures 604 with conductive structures 112 in both the upper deck 304 and the lower deck 302 of the stack structure 108, and the slit structure 116 fabrication completed (e.g., FIG. 1, FIG. 25) to form the microelectronic device structure 300 (FIG. 3, FIG. 4) or the microelectronic device structure 2600 (FIG. 26, FIG. 4).

In other embodiments, as discussed above, the lower deck 302 and the upper deck 304 (FIG. 3, FIG. 26) are formed together, such that the illustrated stack structure 602 or stack structure 108 previously described with reference to FIG. 6 through FIG. 25 represent all (e.g., both) decks (e.g., the lower deck 302 and the upper deck 304) of the microelectronic device structure 300 illustrated in FIG. 3 or the microelectronic device structure 2600 illustrated in FIG. 26.

In some embodiments, the pillars 124 are formed—in one or both decks (e.g., the lower deck 302, the upper deck 304), after forming the conductive structures 112 of the stack structure 108. For example, the processing stage previously described with reference to FIG. 6 may be followed by the slit 1902 formation previously described with reference to FIG. 19, the sacrificial structure 604 (FIG. 19) exhumation previously described with reference to FIG. 20, the conductive material(s) 134 formation previously described with reference to FIG. 21, and the formation of the insulative liner 128 and the nonconductive fill material 130 of the slit structure 116 illustrated in FIG. 1. Then, the pillar openings 702 (FIG. 7) may be formed through the stack structure 108 (rather than through the stack structure 602 as in FIG. 7), and the remaining stages of the pillar 124 fabrication completed to form the microelectronic device structure 100 illustrated in FIG. 1 or the microelectronic device structure 2500 illustrated in FIG. 25.

By any of the foregoing methods, a microelectronic device structure is formed that includes pillars with channel structures of multiple sub-regions of different microstructures configured to both facilitate electron mobility (for sufficient string current) and to inhibit chemical species (e.g., oxygen) traversal to an exterior surface of the channel material so as to avoid data leakage. Moreover, the channel structures may be formed with relatively thin walls, to facilitate device scaling.

With reference to FIG. 27, illustrated is a partial cutaway, perspective, schematic illustration of a portion of a microelectronic device 2700 (e.g., a memory device, such as a 3D NAND Flash memory device) including a microelectronic device structure 2702. The microelectronic device structure 2702 may be substantially similar to a microelectronic device structure previously described herein (e.g., the microelectronic device structure 300 (FIG. 3) including the microelectronic device structure 100 (FIG. 1); the microelectronic device structure 2600 (FIG. 26) including the microelectronic device structure 2500 (FIG. 25)).

As illustrated in FIG. 27, the microelectronic device structure 2702 may include a staircase structure 2704 (which may correspond to, e.g., the aforementioned staircase portion of the microelectronic device structure 300 of FIG. 3 and/or of the microelectronic device structure 2600 of FIG. 26). The staircase structure 2704 may define contact regions for connecting access lines 2706 to conductive tiers 2708 (e.g., conductive layers, conductive plates, such as the conductive structures 112 (e.g., FIG. 1, FIG. 25) of a stack structure (e.g., the stack structure 108 (e.g., FIG. 1, FIG. 25)) in a deck (e.g., either or both the lower deck 302 (FIG. 3, FIG. 26) and/or the upper deck 304 (FIG. 3, FIG. 26)) of the microelectronic device structure 2702.

The microelectronic device structure 2702 may include pillars (e.g., the pillars 124 of FIG. 3 and/or FIG. 26) forming strings 2710 of memory cells 2712 (e.g., one or more of the memory cells 502′ of FIG. 5A and/or the memory cells 502″ of FIG. 5B). The pillars forming the strings 2710 of memory cells 2712 may extend at least somewhat vertically (e.g., in the Z-direction) and orthogonally relative to the conductive tiers 2708, relative to data lines 2714 (e.g., bit lines, digit lines), relative to a source tier 2716 (e.g., the source region 120 of FIG. 3 and/or of FIG. 26), relative to access lines 2706, relative to first select gates 2718 (e.g., upper select gates, such as drain select gates (SGDs), which may include one or more regions configured as drain-side GIDL region(s)), relative to select lines 2720, and/or relative to one or more second select gates 2722 (e.g., lower select gate(s), such as source select gates (SGSs), which may include one or more regions configured as source-side GIDL region(s)).

The first select gates 2718, the conductive tiers 2708, and the second select gates 2722 may be horizontally divided (e.g., in the X-axis direction) into multiple blocks 2724 (e.g., blocks 308 (FIG. 3, FIG. 4, FIG. 26)) spaced apart (e.g., in the X-axis direction) from one another by slits 2726 (e.g., slit structures 116 (FIG. 1, FIG. 3, FIG. 4, FIG. 25, FIG. 26)).

Vertical conductive contacts 2728 may electrically couple components to each other, as illustrated. For example, select lines 2720 may be electrically coupled to the first select gates 2718, and the access lines 2706 may be electrically coupled to the conductive tiers 2708.

The microelectronic device 2700 may also include a control unit 2730 positioned under the memory array (e.g., the pillar array portions 310 (FIG. 3, FIG. 26)). The control unit 2730 may include control logic devices configured to control various operations of other features (e.g., the memory strings 2710, the memory cells 2712) of the microelectronic device 2700. By way of non-limiting example, the control unit 2730 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and/or other chip/deck control circuitry. The control unit 2730 may be electrically coupled to the data lines 2714, the source tier 2716, the access lines 2706, the first select gates 2718, and/or the second select gates 2722, for example. In some embodiments, the control unit 2730 may be configured as and/or include CMOS (complementary metal-oxide-semiconductor) circuitry. In such embodiments, the control unit 2730 may be characterized as having a “CMOS under Array” (“CuA”) configuration. Accordingly, the control unit 2730 may be included in the CMOS region 312 of FIG. 3 and/or FIG. 26.

The first select gates 2718 may extend horizontally in a first direction (e.g., the Y-axis direction) and may be coupled to respective first groups of strings 2710 of memory cells 2712 at a first end (e.g., an upper end) of the strings 2710. The second select gates 2722 may be formed in a substantially planar configuration and may be coupled to the strings 2710 at a second, opposite end (e.g., a lower end) of the strings 2710 of memory cells 2712.

The data lines 2714 may extend horizontally in a second direction (e.g., in the X-axis direction) that is at an angle (e.g., perpendicular) to the first direction in which the first select gates 2718 extend. The data lines 2714 may be coupled to respective second groups of the strings 2710 at the first end (e.g., the upper end) of the strings 2710. A first group of strings 2710 coupled to a respective first select gate 2718 may share a particular string 2710 with a second group of strings 2710 coupled to a respective data line 2714. Thus, a particular string 2710 may be selected at an intersection of a particular first select gate 2718 and a particular data line 2714. Accordingly, the first select gates 2718 may be used for selecting memory cells 2712 of the strings 2710 of memory cells 2712.

The conductive tiers 2708 (e.g., word lines, word line plates) may extend in respective horizontal planes. The conductive tiers 2708 may be stacked vertically, such that each conductive tier 2708 is coupled to all of the strings 2710 of memory cells 2712 in a respective block 2724, and the strings 2710 of the memory cells 2712 extend vertically through the stack(s) (e.g., decks, such as the lower deck 302 and the upper deck 304 of FIG. 3, FIG. 26) of conductive tiers 2708 of the respective block 2724. The conductive tiers 2708 may be coupled to, or may form control gates of, the memory cells 2712 to which the conductive tiers 2708 are coupled. Each conductive tier 2708 may be coupled to one memory cell 2712 of a particular string 2710 of memory cells 2712.

The first select gates 2718 and the second select gates 2722 may operate to select a particular string 2710 of the memory cells 2712 between a particular data line 2714 and the source tier 2716. Thus, a particular memory cell 2712 may be selected and electrically coupled to one of the data lines 2714 by operation of (e.g., by selecting) the appropriate first select gate 2718, second select gate 2722, and the conductive tier 2708 that are coupled to the particular memory cell 2712.

The staircase structure 2704 may be configured to provide electrical connection between the access lines 2706 and the conductive tiers 2708 through the vertical conductive contacts 2728. In other words, a particular level of the conductive tiers 2708 may be selected via one of the access lines 2706 that is in electrical communication with a respective one of the conductive contacts 2728 in electrical communication with the particular conductive tier 2708.

The data lines 2714 may be electrically coupled to the strings 2710 of memory cells 2712 through conductive structures 2732.

Microelectronic devices (e.g., the microelectronic device 2700) including microelectronic device structures (e.g., the microelectronic device structure 100 of FIG. 1, the microelectronic device structure 300 of FIG. 3, the microelectronic device structure 2500 of FIG. 25, and/or the microelectronic device structure 2600 of FIG. 26) may be used in embodiments of electronic systems of the disclosure. For example, FIG. 28 is a block diagram of an electronic system 2800, in accordance with embodiments of the disclosure. The electronic system 2800 may comprise, for example, a computer or computer hardware component, a server or other networking hardware component, a cellular telephone, a digital camera, a personal digital assistant (PDA), a portable media (e.g., music) player, a Wi-Fi or cellular-enabled tablet (e.g., an iPAD® or SURFACE® tablet, an electronic book, a navigation device), etc.

The electronic system 2800 includes at least one memory device 2802. The memory device 2802 may include, for example, one or more embodiment(s) of a microelectronic device and/or structure previously described herein (e.g., the microelectronic device 2700 of FIG. 27, the microelectronic device structure 100 of FIG. 1, the microelectronic device structure 300 of FIG. 3, the microelectronic device structure 2500 of FIG. 25, and/or the microelectronic device structure 2600 of FIG. 26), e.g., with structures formed according to embodiments previously described herein.

The electronic system 2800 may further include at least one electronic signal processor device 2804 (often referred to as a “microprocessor”). The processor device 2804 may, optionally, include an embodiment of a microelectronic device and/or a microelectronic device structure previously described herein (e.g., the microelectronic device 2700 of FIG. 27, the microelectronic device structure 100 of FIG. 1, the microelectronic device structure 300 of FIG. 3, the microelectronic device structure 2500 of FIG. 25, and/or the microelectronic device structure 2600 of FIG. 26). The electronic system 2800 may further include one or more input devices 2806 for inputting information into the electronic system 2800 by a user, such as, for example, a mouse or other pointing device, a keyboard, a touchpad, a button, or a control panel. The electronic system 2800 may further include one or more output devices 2808 for outputting information (e.g., visual or audio output) to a user such as, for example, a monitor, a display, a printer, an audio output jack, a speaker, etc. In some embodiments, the input device 2806 and the output device 2808 may comprise a single touchscreen device that can be used both to input information into the electronic system 2800 and to output visual information to a user. The input device 2806 and the output device 2808 may communicate electrically with one or more of the memory device 2802 and the electronic signal processor device 2804.

Accordingly, disclosed is an electronic system comprising an input device, an output device, a processor device, and a memory device. The processor device is operably coupled to the input device and to the output device. The memory device is operably coupled to the processor device. The memory device comprises at least one microelectronic device structure. The at least one microelectronic device structure comprises a stack structure and pillars extending through the stack structure. The stack structure comprises insulative structures vertically interleaved with conductive structures. The pillars comprise a hollow channel structure comprising sub-regions of semiconductor material. At least one of the sub-regions comprises a different microstructure than at least one other of the sub-regions.

With reference to FIG. 29, shown is a block diagram of a processor-based system 2900. The processor-based system 2900 may include various microelectronic devices (e.g., the microelectronic device 2700 of FIG. 27) and microelectronic device structures (e.g., the microelectronic device structure 100 of FIG. 1, the microelectronic device structure 300 of FIG. 3, the microelectronic device structure 2500 of FIG. 25, and/or the microelectronic device structure 2600 of FIG. 26) manufactured in accordance with embodiments of the present disclosure. The processor-based system 2900 may be any of a variety of types, such as a computer, a pager, a cellular phone, a personal organizer, a control circuit, or another electronic device. The processor-based system 2900 may include one or more processors 2902, such as a microprocessor, to control the processing of system functions and requests in the processor-based system 2900. The processor 2902 and other subcomponents of the processor-based system 2900 may include microelectronic devices (e.g., the microelectronic device 2700 of FIG. 27) and microelectronic device structures (e.g., the microelectronic device structure 100 of FIG. 1, the microelectronic device structure 300 of FIG. 3, the microelectronic device structure 2500 of FIG. 25, and/or the microelectronic device structure 2600 of FIG. 26) manufactured in accordance with embodiments of the present disclosure.

The processor-based system 2900 may include a power supply 2904 in operable communication with the processor 2902. For example, if the processor-based system 2900 is a portable system, the power supply 2904 may include one or more of a fuel cell, a power scavenging device, permanent batteries, replaceable batteries, and/or rechargeable batteries. The power supply 2904 may also include an AC adapter; therefore, the processor-based system 2900 may be plugged into a wall outlet, for example. The power supply 2904 may also include a DC adapter such that the processor-based system 2900 may be plugged into a vehicle cigarette lighter or a vehicle power port, for example.

Various other devices may be coupled to the processor 2902 depending on the functions that the processor-based system 2900 performs. For example, a user interface 2906 may be coupled to the processor 2902. The user interface 2906 may include one or more input devices, such as buttons, switches, a keyboard, a light pen, a mouse, a digitizer and stylus, a touch screen, a voice recognition system, a microphone, or a combination thereof. A display 2908 may also be coupled to the processor 2902. The display 2908 may include an LCD display, an SED display, a CRT display, a DLP display, a plasma display, an OLED display, an LED display, a three-dimensional projection, an audio display, or a combination thereof. Furthermore, an RF subsystem/baseband processor 2910 may also be coupled to the processor 2902. The RF subsystem/baseband processor 2910 may include an antenna that is coupled to an RF receiver and to an RF transmitter. A communication port 2912, or more than one communication port 2912, may also be coupled to the processor 2902. The communication port 2912 may be adapted to be coupled to one or more peripheral devices 2914 (e.g., a modem, a printer, a computer, a scanner, a camera) and/or to a network (e.g., a local area network (LAN), a remote area network, an intranet, or the Internet).

The processor 2902 may control the processor-based system 2900 by implementing software programs stored in the memory (e.g., system memory 2916). The software programs may include an operating system, database software, drafting software, word processing software, media editing software, and/or media-playing software, for example. The memory (e.g., the system memory 2916) is operably coupled to the processor 2902 to store and facilitate execution of various programs. For example, the processor 2902 may be coupled to system memory 2916, which may include one or more of spin torque transfer magnetic random access memory (STT-MRAM), magnetic random access memory (MRAM), dynamic random access memory (DRAM), static random access memory (SRAM), racetrack memory, and/or other known memory types. The system memory 2916 may include volatile memory, nonvolatile memory, or a combination thereof. The system memory 2916 is typically large so it can store dynamically loaded applications and data. In some embodiments, the system memory 2916 may include semiconductor devices (e.g., the microelectronic device 2700 of FIG. 27) and structures (e.g., the microelectronic device structure 100 of FIG. 1, the microelectronic device structure 300 of FIG. 3, the microelectronic device structure 2500 of FIG. 25, and/or the microelectronic device structure 2600 of FIG. 26), described above, or a combination thereof.

The processor 2902 may also be coupled to nonvolatile memory 2918, which is not to suggest that system memory 2916 is necessarily volatile. The nonvolatile memory 2918 may include one or more of STT-MRAM, MRAM, read-only memory (ROM) (e.g., EPROM, resistive read-only memory (RROM)), and Flash memory to be used in conjunction with the system memory 2916. The size of the nonvolatile memory 2918 is typically selected to be just large enough to store any necessary operating system, application programs, and fixed data. Additionally, the nonvolatile memory 2918 may include a high-capacity memory (e.g., disk drive memory, such as a hybrid-drive including resistive memory or other types of nonvolatile solid-state memory, for example). The nonvolatile memory 2918 may include microelectronic devices (e.g., the microelectronic device 2700 of FIG. 27) and structures (e.g., the microelectronic device structure 100 of FIG. 1, the microelectronic device structure 300 of FIG. 3, the microelectronic device structure 2500 of FIG. 25, and/or the microelectronic device structure 2600 of FIG. 26) described above, or a combination thereof.

While the disclosed structures, apparatus (e.g., devices), systems, and methods are susceptible to various modifications and alternative forms in implementation thereof, specific embodiments have been shown by way of example in the drawings and have been described in detail herein. However, the disclosure is not intended to be limited to the particular forms disclosed. Rather, the disclosure encompasses all modifications, combinations, equivalents, variations, and alternatives falling within the scope of the disclosure as defined by the following appended claims and their legal equivalents.

What is claimed is:

1. A microelectronic device, comprising:
a stack structure comprising a vertically alternating sequence of insulative structures and conductive structures arranged in tiers; and
at least one pillar extending through the stack structure, the at least one pillar comprising:
at least one insulative material; and
a channel structure horizontally surrounding the at least one insulative material and comprising sub-regions of semiconductor material, at least one of the sub-regions exhibiting a different microstructure than at least one other of the sub-regions.

2. The microelectronic device of claim 1, wherein an inner sub-region, of the sub-regions of semiconductor material, comprises large grains of polysilicon, the large grains having an average grain size of greater than about 0.01 μm.

3. The microelectronic device of claim 2, wherein an outer sub-region, of the sub-regions of semiconductor material, comprises small grains of polysilicon, the small grains having an average grain size of less than about 0.01 μm.

4. The microelectronic device of claim 3, wherein the small grains of polysilicon comprise a carbon dopant.

5. The microelectronic device of claim 2, wherein, of the sub-regions of semiconductor material, an outer sub-region comprises amorphous silicon.

6. The microelectronic device of claim 5, wherein the outer sub-region further comprises a carbon dopant.

7. The microelectronic device of claim 5, wherein the outer sub-region further comprises a trace amount of hydrogen.

8. The microelectronic device of claim 2, wherein the inner sub-region is directly adjacent the at least one insulative material of the at least one pillar.

9. The microelectronic device of claim 1, wherein the sub-regions of semiconductor material consist of an inner sub-region directly adjacent an outer sub-region.

10. The microelectronic device of claim 1, wherein an outer sub-region is directly adjacent a portion of a source region below the stack structure.

11. The microelectronic device of claim 1, wherein, of the sub-regions of the semiconductor material, an inner sub-region extends through a base portion of an outer sub-region.

12. The microelectronic device of claim 11, wherein the inner sub-region directly contacts a source region below the stack structure.

13. The microelectronic device of claim 1, wherein, of the sub-regions of the semiconductor material, an outer sub-region constitutes less than about 50% of a total horizontal thickness of the channel structure.

14. The microelectronic device of claim 13, wherein the total horizontal thickness of the channel structure is less than about 10 nm.

15. The microelectronic device of claim 1, wherein, of the sub-regions of the semiconductor material, an outer sub-region has a horizontal thickness of less than about 3 nm.

16. A method of forming a microelectronic device, the method comprising:
forming a tiered stack structure on a base structure, the tiered stack structure comprising a vertically alternating sequence of insulative structures and other structures arranged in tiers;
forming a pillar opening through the tiered stack structure and at least to the base structure;
forming cell materials in the pillar opening;
on the cell materials, forming an outer sub-region of a channel structure, the outer sub-region comprising at least one of amorphous silicon and small grains of polysilicon;
on the outer sub-region, forming an inner sub-region of the channel structure, the inner sub-region comprising large grains of polysilicon, the large grains of polysilicon having an average grain size that is greater than an average grain size of the small grains of polysilicon; and
forming at least one insulative material on the inner sub-region of the channel structure to form a core of a pillar.

17. The method of claim 16, wherein forming the outer sub-region comprises depositing the at least one of the amorphous silicon and the small grains of polysilicon to an initial thickness substantially equal a final thickness of the outer sub-region.

18. The method of claim 16, wherein forming the outer sub-region comprises depositing the at least one of the amorphous silicon and the small grains of polysilicon to a final thickness of less than about 5 nm.

19. The method of claim 16, wherein forming the inner sub-region of the channel structure comprises:
forming the polysilicon of the inner sub-region to an initial thickness greater than a final thickness of the inner sub-region; and
thinning the polysilicon of the inner sub-region to the final thickness of the inner sub-region.

20. The method of claim 16, further comprising, before forming the outer sub-region of the channel structure:
forming a sacrificial liner material on the cell materials;
removing a base portion of the sacrificial liner material;
forming an additional opening through a base portion of the cell materials to expose a portion of the base structure; and
removing the sacrificial liner material,
wherein forming the outer sub-region of the channel structure further comprises forming the outer sub-region of the channel structure in the additional opening in direct physical contact with the portion of the base structure.

21. The method of claim 16, further comprising, after forming the outer sub-region of the channel structure on the cell materials:
removing a base portion of the outer sub-region; and
forming an additional opening through a base portion of the cell materials to expose a portion of the base structure,
wherein forming the inner sub-region of the channel structure further comprises forming the inner sub-region of the channel structure in the additional opening in direct physical contact with the portion of the base structure.

22. The method of claim 16, wherein forming the outer sub-region of the channel structure comprises doping the at least one of the amorphous silicon and the small grains of polysilicon with carbon.

23. The method of claim 16, wherein:
forming the outer sub-region comprises depositing silicon using hydrogen-rich precursors selected from disilane precursors and trisilane precursors; and
forming the inner sub-region comprises depositing additional silicon using a monosilane precursor.

24. The method of claim 16, wherein forming the inner sub-region follows forming the outer sub-region without purging and without removing structures from a deposition chamber in which the formation of the inner sub-region and the formation of the outer sub-region are performed.

25. The method of claim 16, further comprising replacing the other structures, of the tiered stack structure, with conductive structures.

26. An electronic system, comprising:
an input device;
an output device;
a processor device operably coupled to the input device and to the output device; and
a memory device operably coupled to the processor device and comprising at least one microelectronic device structure, the at least one microelectronic device structure comprising:
a stack structure comprising insulative structures vertically interleaved with conductive structures; and
pillars extending through the stack structure, the pillars comprising a hollow channel structure comprising sub-regions of semiconductor material, at least one of the sub-regions comprising a different microstructure than at least one other of the sub-regions.
